(19) United States
(12) Patent Application Publication
(10) Pub. No.: US 2026/0271381 A1
(43) Pub. Date: Sep. 10, 2026

(54) GATE CONTACT STRUCTURES IN SEMICONDUCTOR DEVICES

(71) Applicant: Taiwan Semiconductor Manufacturing Company, Ltd., Hsinchu (TW)

(72) Inventors: Tsung-Chieh HSIAO, Changhua (TW); Cheng-Yi PENG, Taipei (TW); Chih-Lin WANG, Hsinchu (TW)

(73) Assignee: Taiwan Semiconductor Manufacturing Company, Ltd., Hsinchu (TW)

(21) Appl. No.: 19/344,009

(22) Filed: Sep. 29, 2025

Related U.S. Application Data
(60) Provisional application No. 63/769,468, filed on Mar. 10, 2025.

(51) Int. Cl. H10D 84/83; H10D 30/00; H10D 30/01; H10D 30/43; H10D 62/10; H10D 62/13; H10D 84/01

(52) U.S. Cl. CPC H10D 84/832; H10D 30/014; H10D 30/0191; H10D 30/43; H10D 30/503; H10D 62/102; H10D 62/121; H10D 62/151; H10D 84/0135; H10D 84/0149

(57) ABSTRACT

A semiconductor device and a method of fabricating the semiconductor device are disclosed. The semiconductor device includes a substrate, first and second nanostructured channel regions, and a gate structure. The gate structure includes first and second metal layers surrounding the first and second nanostructured channel regions and a gate metal layer disposed on the first and second metal layers. The first and second metal layers are different from each other. The semiconductor device further includes an isolation structure disposed between and in contact with the first and second nanostructured channel regions and a first contact structure disposed on surfaces of the isolation structure and the first and second metal layers that face the substrate.

### CROSS-REFERENCE TO RELATED APPLICATIONS

This application claims the benefit of U.S. Provisional Patent Application No. 63/769,468, titled “Slot Backside Gate Contacts for Forksheet and Zero Gate Height,” filed Mar. 10, 2025, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (FinFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIGS. 1B, 1C, 1D, 1E, 1F, 1G, and 1H illustrate different cross-sectional views of a semiconductor device with contact structures, in accordance with some embodiments.

FIGS. 1I and 1J illustrate different top-down views of a semiconductor device with contact structures, in accordance with some embodiments.

FIG. 2A illustrates an isometric view of another semiconductor device, in accordance with some embodiments.

FIGS. 2B, 2C, 2D, and 2E illustrate different cross-sectional views of another semiconductor device with contact structures, in accordance with some embodiments.

FIG. 2F illustrates a top-down view of another semiconductor device with contact structures, in accordance with some embodiments.

FIG. 3 is a flow diagram of a method for fabricating a semiconductor device with contact structures, in accordance with some embodiments.

FIGS. 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, and 25B illustrate cross-sectional views of a semiconductor device with contact structures at various stages of its fabrication process, in accordance with some embodiments.

FIG. 26 is a flow diagram of a method for fabricating another semiconductor device with contact structures, in accordance with some embodiments.

FIGS. 27A, 27B, 28A, 28B, 29A, and 29B illustrate cross-sectional views of another semiconductor device with contact structures at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, +2%, ±3%, +4%, ±5%, ±10%, ±10-15%, ±15~20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

A semiconductor device can include an n-type GAA FET (NFET) and a p-type GAA FET (PFET) having first and second nanostructured channel regions, respectively. The semiconductor device can further include an isolation structure (also referred to as “a dielectric wall”) between the first and second nanostructured channel regions and a gate structure shared by the NFET and PFET. The gate structure can include (i) a high-k gate dielectric layer surrounding the first and second nanostructured channel regions and the isolation structure, (ii) an n-type work function metal (nWFM) layer surrounding the first nanostructured channel regions, (iii) a p-type WFM (pWFM) layer surrounding the second nanostructured channel regions, and (iv) a gate metal layer disposed on the nWFM layer and the pWFM layer. The semiconductor device can further include a front contact structure on a front surface of the gate structure to provide electrical signals from a power rail to both the NFET and PFET. One of the challenges of fabricating such semiconductor devices is the formation of reliable front contact structures. The front contact structure can undesirably contact a top surface of the isolation structure due to non-uniformity of the gate metal layer thickness overlying the isolation structure. The non-uniformity of the gate metal layer thickness can be a result of the chemical mechanical polishing (CMP) process used in the formation of the gate metal layer. The undesirable contact between the front contact structure and the isolation structure reduces the contact area between the front contact structure and the gate structure, which increases the gate contact resistance and degrades device performance.

To address the abovementioned challenges, the present disclosure provides example semiconductor devices with back contact structures on back surfaces of the gate structures to improve reliability and performance of the semiconductor devices. The present disclosure also provides example methods of forming such semiconductor devices. In some embodiments, the back contact structure can be disposed on and in contact with back surfaces of the nWFM layer and the pWFM layer of the gate structure. In some embodiments, the back contact structure can also surround the back surface and/or the sidewalls of the isolation structure between the first and second nanostructured channel regions. In some embodiments, the back contact structure can be formed by replacing the substrate and fin portions under the first and second nanostructured channel regions and the isolation structure with the back contact structure. As a result, a larger contact area can be formed between the back contact structure and the gate structures, which can significantly reduce the gate contact resistance and improve device performance. In addition, by replacing the substrate and fin portions with the back contact structure, the formation of isolation structures under source/drain regions of the NFET and PFET can be eliminated. Because, by removing the substrate and fin portions under the gate structure, the current leakage path between the source/drain regions are removed, thus eliminating the need for the isolation structures. Thus, the back contact structure can perform a dual function of (i) providing electrical signals from a power rail to both the NFET and PFET, and (ii) preventing current leakage between source/drain regions.

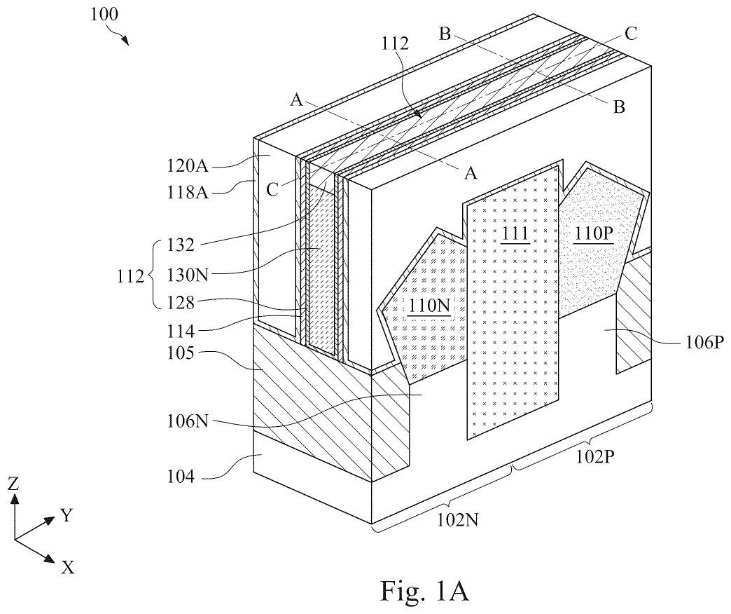

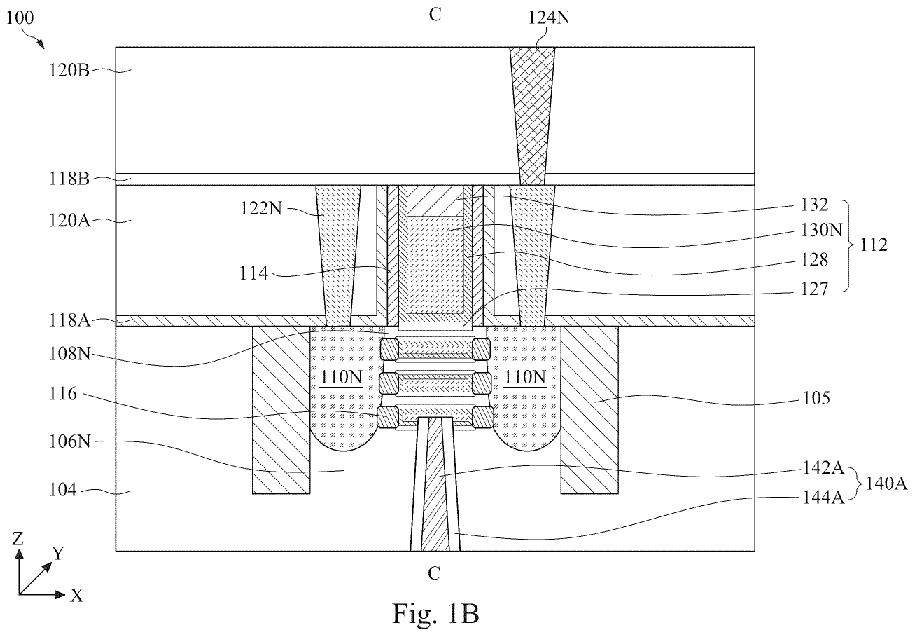

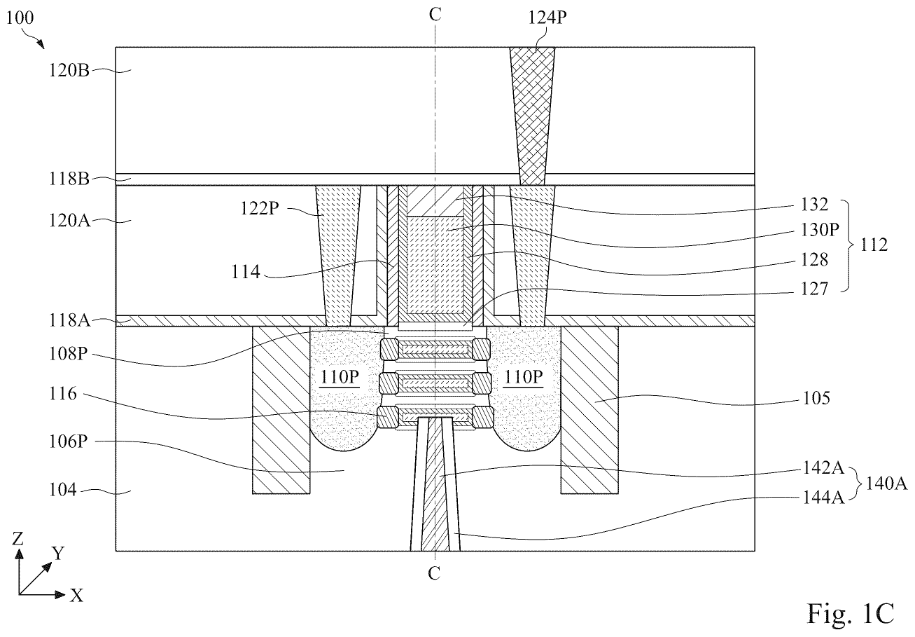

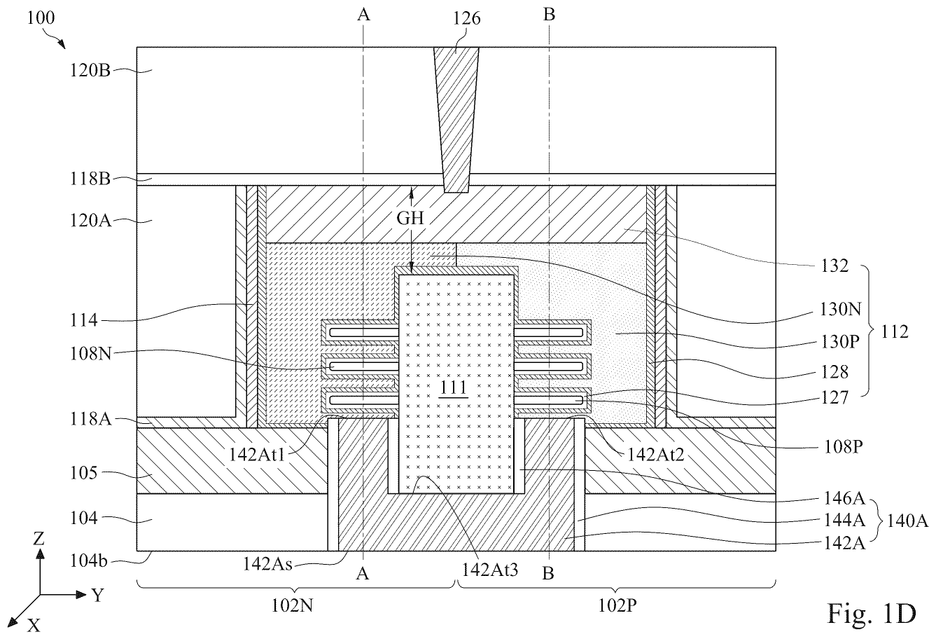

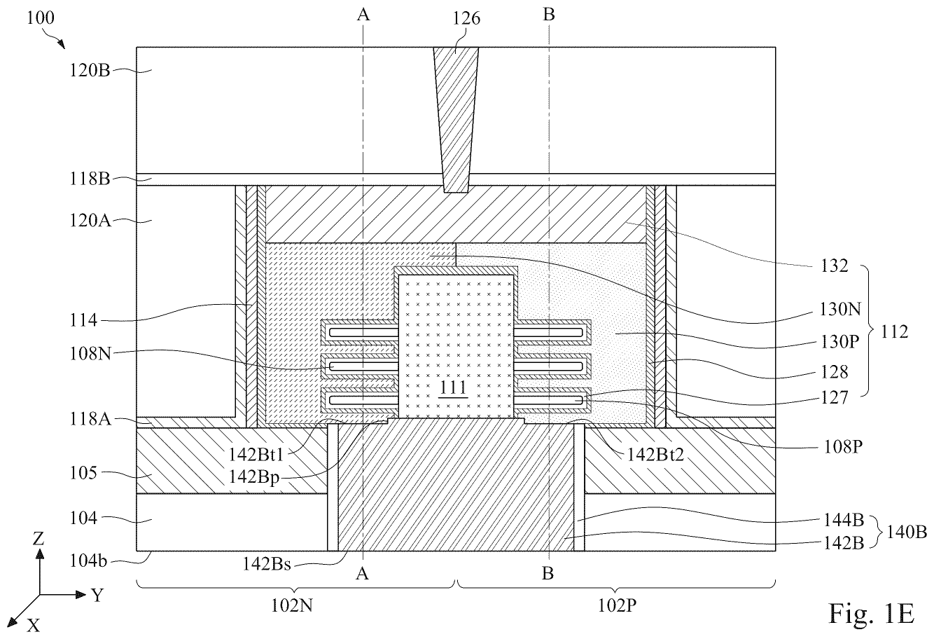

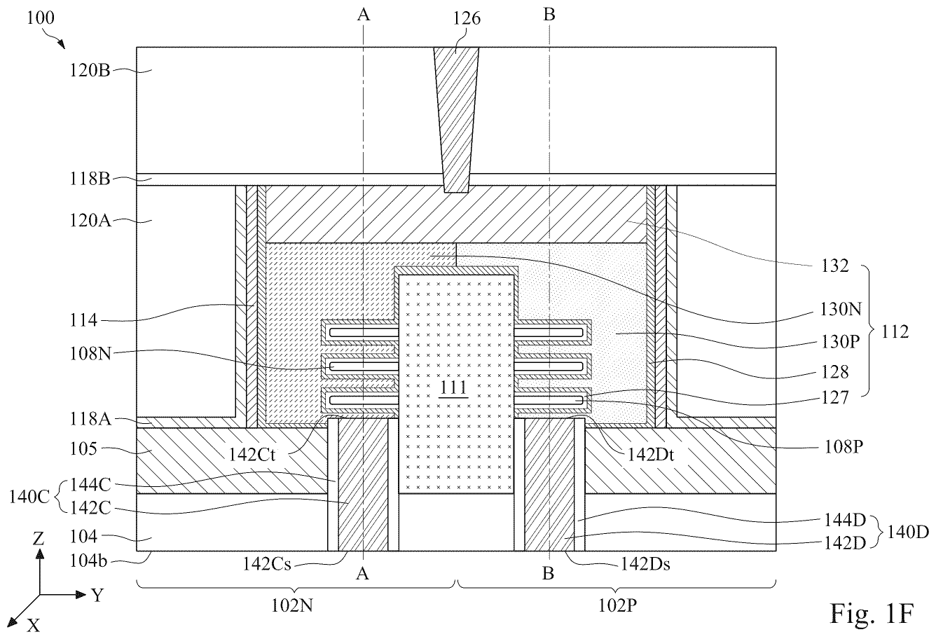

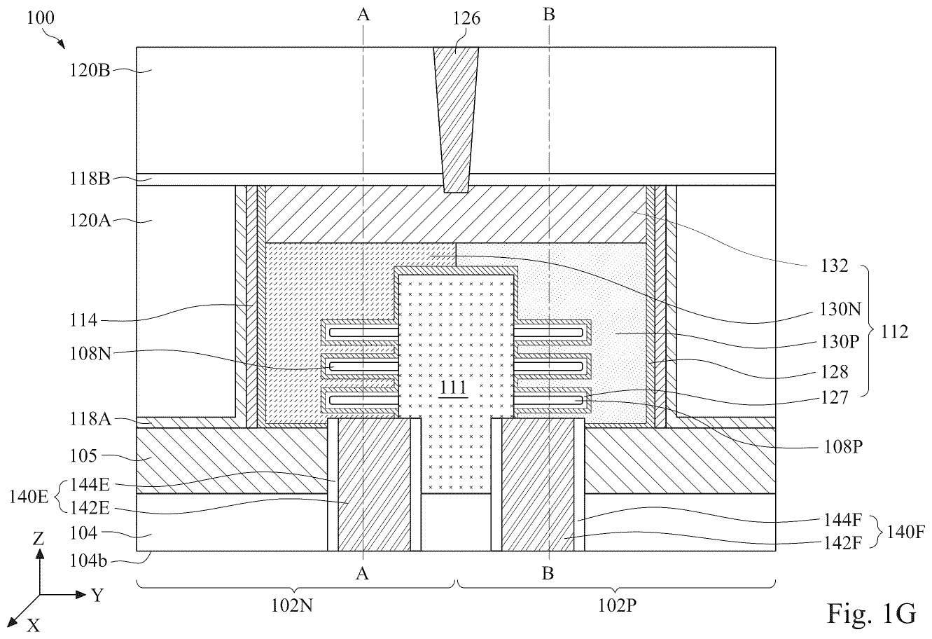

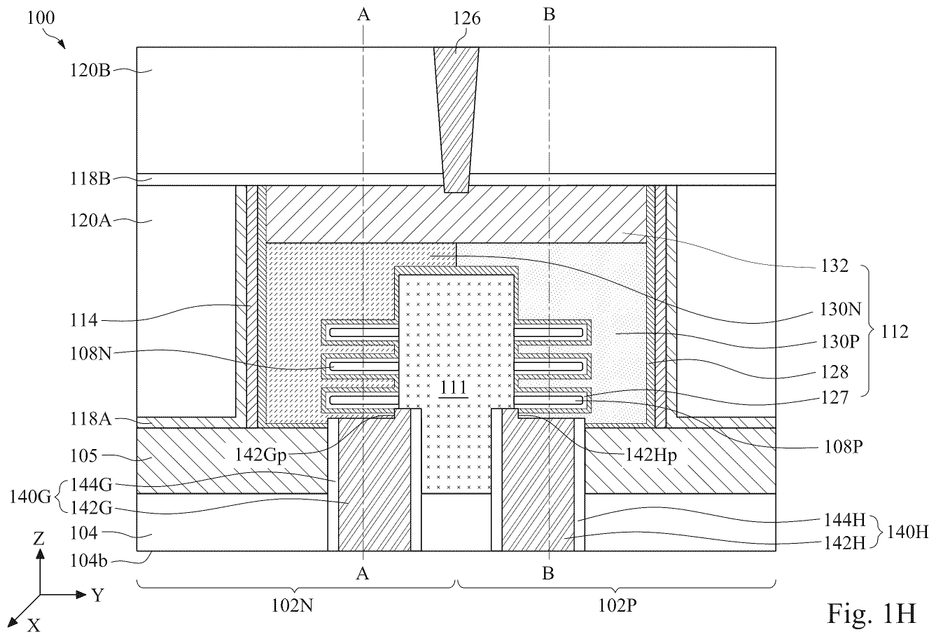

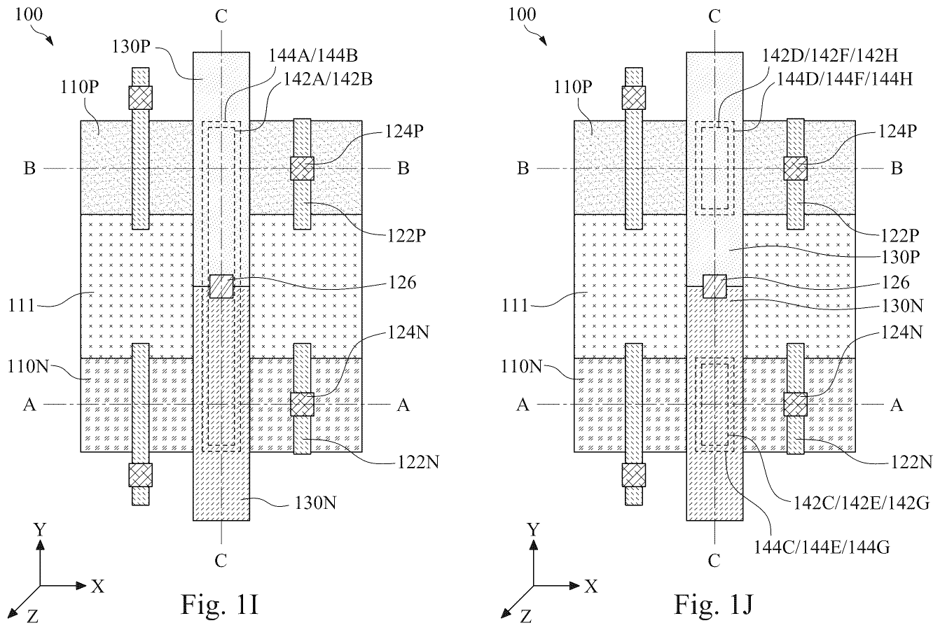

FIG. 1A illustrates an isometric view of a semiconductor device 100 having an NFET 102N and a PFET 102P, according to some embodiments. In some embodiments, NFET 102N can represent an n-type GAA FET and PFET 102P can represent a p-type GAA FET. FIG. 1B illustrates a cross-sectional view of semiconductor device 100 along line A-A of FIG. 1A and FIG. 1C illustrates a cross-sectional view of semiconductor device 100 along line B-B of FIG. 1A, according to some embodiments. FIGS. 1D-1H illustrate different cross-sectional views of semiconductor device 100 along line D-D of FIG. 1A, according to some embodiments. FIGS. 1I and 1J illustrate different top-down views of semiconductor device 100, according to some embodiments. FIGS. 1B-1J illustrate views with additional structures that are not shown in FIG. 1A for simplicity. The discussion of elements in FIGS. 1A-1J with the same annotations applies to each other, unless mentioned otherwise.

Semiconductor device 100 can include a substrate 104 and NFET 102N and PFET 102 can be disposed on different regions of substrate 104. There may be other FETs and/or structures (e.g., isolation structures) formed on substrate 104. In some embodiments, substrate 104 can be a semiconductor material, such as silicon (Si), Ge, silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include shallow trench isolation (STI) regions 105 disposed on substrate 104. In some embodiments, STI regions 105 can include an insulating material, such as silicon oxide (SiO2), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOx).

Referring to FIGS. 1A, 1B, and 1D, in some embodiments, NFET 102N can include (i) a fin-shaped base structure 106N, (also referred to as a “sheet base 106N” or a “fin base 106N”) disposed on substrate 104, (ii) nanostructured channel regions 108N disposed on base structure 106N, (iii) S/D regions 110N disposed adjacent to nanostructured channel regions 108N, (iv) inner gate spacers 116 (not visible in FIGS. 1A and 1D), (v) contact structures 122N (not shown in FIG. 1A and not visible in FIG. 1D) disposed on S/D regions 110N, and (vi) a via structure 124N (not shown in FIG. 1A and not visible in FIG. 1D) disposed on contact structure 122N.

Similarly, referring to FIGS. 1A, 1C, and 1D, in some embodiments, PFET 102P can include (i) a fin-shaped base structure 106P, (also referred to as a “sheet base 106P” or a “fin base 106P”) disposed on substrate 104, (ii) nanostructured channel regions 108P disposed on base structure 106P, (iii) S/D regions 110P disposed adjacent to nanostructured channel regions 108P, (iv) inner gate spacers 116 (not visible in FIGS. 1A and 1D), (v) contact structures 122P (not shown in FIG. 1A and not visible in FIG. 1D) disposed on S/D regions 110P, and (vi) a via structure 124P (not shown in FIG. 1A and not visible in FIG. 1D) disposed on contact structure 122N.

In some embodiments, semiconductor device 100 further includes (i) an isolation structure 111 (also referred to as “a dielectric wall 111”), (ii) a gate structure 112 shared by NFET 102N and PFET 102P, (iii) outer gate spacers 114, (iv) etch stop layers (ESLs) 118A disposed directly on S/D regions 110N and 110P and on isolation structure 111, (v) interlayer dielectric (ILD) layers 120A disposed directly on ESLs 118A, (vi) ESLs 118B disposed directly on gate structure 112, outer spacers 114, ESLs 118A, and ILD layers 120A, (vii) ILD layers 120B disposed directly on ESLs 118B, (viii) a front contact structure 126 disposed on a front surface of gate structure 112, and (ix) a back contact structure 140A disposed on a back surface of gate structure 112.

In some embodiments, base structures 106N and 106P can include a material similar to substrate 104. Base structures 106N and 106P can have elongated sides extending along an X-axis. In some embodiments, nanostructured channel regions 108N and 108P can be in the form of nanosheets, nanowires, nanorods, nanotubes, or other suitable nanostructured shapes. As used herein, the term “nanostructured” defines a structure, layer, and/or region as having a horizontal dimension (e.g., along an X-and/or Y-axis) and/or a vertical dimension (e.g., along a Z-axis) less than about 100 nm, for example about 90 nm, about 50 nm, about 10 nm, or other values less than about 100 nm. Nanostructured channel regions 108N and 108P can include semiconductor materials similar to or different from substrate 104. In some embodiments, nanostructured channel regions 108N and 108P can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, the materials of nanostructured channel regions 108N and 108P can be different from each other. In some embodiments, nanostructured channel regions 108N can include Si and nanostructured channel regions 108P can include SiGe. Though three nanostructured channel regions 108N and three nanostructured channel regions 108P are shown under gate structure 112, NFET 102N and PFET 102P can have any number of nanostructured channel regions 108N and 108P. Though rectangular cross-sections of nanostructured channel regions 108N and 108P are shown, nanostructured channel regions 108N and 108P can have cross-sections of other geometric shapes (e.g., circular, elliptical, triangular, or polygonal).

In some embodiments, S/D regions 110N and 110P extend into substrate 104, as shown in FIGS. 1B and 1C. In some embodiments, heights of S/D regions 110N along a Z-axis and widths of S/D regions 110N along an X-axis are different from each other. Similarly, heights of S/D regions 110P along a Z-axis and widths of S/D regions 110P along an X-axis are different from each other. In some embodiments, S/D regions 110N can include an epitaxially-grown semiconductor material, such as Si, and n-type dopants, such as phosphorus and other suitable n-type dopants. S/D regions 110P can include an epitaxially-grown semiconductor material, such as Si and SiGe, and p-type dopants, such as boron and other suitable p-type dopants. Each of S/D regions 110N and 110P may refer to a source or a drain, individually or collectively dependent upon the context.

In some embodiments, isolation structure 111 can be disposed on substrate 104, between S/D regions 110N and 110P, as shown in FIG. 1A, and between nanostructured channel regions 108N and 108P, as shown in FIG. 1D. Isolation structure 111 is not visible in FIGS. 1B and 1C. In some embodiments, isolation structure 111 can extend vertically above top surfaces of S/D regions 110N and 110P, as shown in FIG. 1A and extend vertically above the top surfaces of the topmost nanostructured channel regions 108N and 108P, as shown in FIG. 1D. Isolation structure 111 can electrically isolate nanostructured channel regions 108N and 108P from each other. Also, with the use of isolation structure 111, S/D regions 110N and 110P can be prevented from merging during their epitaxial growth process, as described below.

Referring to FIGS. 1A-1D, gate structure 112 can be a multi-layered structure and can have a gate height GH, which is a height between a top surface of isolation structure 111 and a top surface of gate structure 112. In some embodiments, gate structure 112 can include interfacial oxide (IL) layers 127. IL layers 127 can be disposed directly on sidewalls of nanostructured channel regions 108N and 108P (shown in FIG. 1D) that are not covered by S/D regions 110N and 110P and isolation structure 111 and on top and bottom surfaces of nanostructured channel regions 108N and 108P (shown in FIGS. 1B-1D) that are not covered by outer gate spacers 114 and inner gate spacers 116. In some embodiments, IL layers 127 on nanostructured channel regions 108N can include an oxide of the material of nanostructured channel regions 108N, such as SiO2. In some embodiments, IL layers 127 on nanostructured channel regions 108P can include an oxide of the material of nanostructured channel regions 108P, such as SiO2, SiGeOx, or germanium oxide (GeOx).

In some embodiments, gate structure 112 can further include a high-k (HK) gate dielectric layer 128 disposed directly on (i) IL layers 127 (shown in FIGS. 1B-1D), (ii) STI regions 105 (shown in FIGS. 1A and 1D), (iii) outer gate spacers 114 (shown in FIGS. 1A-1D), and (iv) top surface and sidewall portions of isolation structure 111 (shown in FIG. 1D) that are under gate structure 112 and extend above a top surface of STI region 105 and that are not covered by nanostructured channel regions 108N and 108P and back contact structure 140A. In some embodiments, HK gate dielectric layer 128 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂).

In some embodiments, gate structure 112 can further include nWFM layer 130N (shown in FIGS. 1B and 1D, not visible in FIGS. 1A and 1C) disposed directly on portions of HK gate dielectric layer 128 that surround nanostructured channel regions 108N and that are on a portion of isolation structure 111 in NFET 102N. In some embodiments, nWFM layer 130N may not be present on portions of HK gate dielectric layer 128 that surround nanostructured channel regions 108P in PFET 102P, as shown in FIGS. 1B and 1D. In some embodiments, nWFM layer 130N can include a metal or a metal-containing material with a work function value closer to a conduction band energy than a valence band energy of a material of nanostructured channel regions 108N. In some embodiments, nWFM layer 130N can have a work function value less than about 4.5 eV. In some embodiments, nWFM layer 130N can include titanium aluminum (TiAl), titanium aluminum carbide (TiAIC), tantalum aluminum (TaAl), tantalum aluminum carbide (TaAlC), Al-doped Ti, Al-doped TiN, Al-doped Ta, Al-doped TaN, or other suitable Al-based materials.

In some embodiments, gate structure 112 can further include pWFM layer 130P (shown in FIGS. 1C and 1D, not visible in FIGS. 1A and 1B) disposed directly on portions of HK gate dielectric layer 128 that surround nanostructured channel regions 108P and that are on a portion of isolation structure 111 in PFET 102P. In some embodiments, pWFM layer 130P may not be present on portions of HK gate dielectric layer 128 that surround nanostructured channel regions 108N in NFET 102N, as shown in FIGS. 1C and 1D. In some embodiments, pWFM layer 130P can include a metal or a metal-containing material with a work function value closer to a valence band energy than a conduction band energy of a material of nanostructured channel regions 108P. In some embodiments, pWFM layer 130P can have a work function value equal to or greater than about 4.5 eV. In some embodiments, pWFM layer 130P can include substantially Al-free (e.g., with no Al) Ti-based or Ta-based nitrides or alloys, such as titanium nitride (TiN), titanium silicon nitride (TiSiN), titanium gold (Ti-Au) alloy, titanium copper (Ti-Cu) alloy, tantalum nitride (TaN), tantalum silicon nitride (TaSiN), tantalum gold (Ta-Au) alloy, and tantalum copper (Ta-Cu) alloy.

In some embodiments, gate structure 112 can further include gate metal layer 132 disposed directly on nWFM layer 130N and pWFM layer 130P. In some embodiments, gate metal layers 132 can have a top surface substantially coplanar with top surfaces of HK gate dielectric layer 128 and outer gate spacers 114, as shown in FIGS. 1A-1D. In some embodiments, gate metal layer 132 can include a conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

In some embodiments, outer gate spacers 114 and inner spacers 116 can electrically isolate gate structure 112 from adjacent S/D regions 110N and 106P. In some embodiments, outer gate spacers 114 can be disposed directly on topmost nanostructured channel regions 108N and 108P. In some embodiments, outer gate spacers 114 and inner spacers 116 can include insulating materials, such as SiO₂, SiN, SiON, SiOC, SiCN, SiOCN, and any other suitable insulating materials. In some embodiments, ESLs 118A and 118B can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 120A and 120B can include an insulating material, such as SiO₂, SiN, SiON, SiCN, and SiOCN. In some embodiments, outer gate spacers 114 can have first sidewalls interfacing HK gate dielectric layers 128 and second sidewalls facing away from gate structures 212N and 212P. In some embodiments, a dielectric constant of HK gate dielectric layers 128 is greater than a dielectric constant of outer gate spacers 114. In some embodiments, a thickness of the gate spacer is greater than a thickness of the gate dielectric layer.

In some embodiments, contact structures 122N can be disposed directly on S/D regions 110N and contact structures 122P can be disposed directly on S/D regions 110P. In some embodiments, each of contact structures 122N and 122P can be disposed in and surrounded by ILD layer 120A and ESL 118A. In some embodiments, contact structures 122N and 122P can include a conductive material, such as Co, W, Ru, Al, Mo, Ir, Ni, Osmium (Os), rhodium (Rh), other suitable conductive materials, and a combination thereof. In some embodiments, via structure 124N can be disposed directly on one of contact structures 122N and via structure 124P can be disposed directly on one of contact structures 122P. In some embodiments, via structures 124N and 124P can include a conductive material, such as W, Ru, Al, Mo, Ir, Ni, Os, other suitable conductive materials, and a combination thereof. In some embodiments, the materials of contact structure 122N and via structure 124N are different from each other and the materials of contact structure 122PN and via structure 124P are different from each other. In some embodiments, wherein an electrical conductivity of contact structures 122N and 122P is greater than an electrical conductivity of source/drain regions 110N and 110P, respectively.

In some embodiments, front contact structure 126 (shown in FIG. 1D, not visible in FIGS. 1B and 1C, not shown in FIG. 1A) can be disposed in and surrounded by ILD layer 120B, ESL 118B and gate metal layer 132. In some embodiments, front contact structure 126 can include a conductive material, such as W, Ru, Al, Mo, Ir, Ni, Os, other suitable conductive materials, and a combination thereof. In some embodiments, the bottom surface of front contact structure 126 can be in contact with the top surface of isolation structure 111 due to non-uniformity in thicknesses of gate metal layer 132, nWFM layer 130N, and/or pWFM layer 130P. This uniformity in thicknesses can be a result of CMP process and/or etching processes used in the formation of gate structure 112, described in detail below. Due to the contact between front contact structure 126 and isolation structure 111, the contact area between gate metal layer 132 and front contact structure 126 may be reduced, which increases the gate resistance and the gate contact resistance. To reduce the gate resistance and the gate contact resistance of semiconductor device 100 and improve device performance, back contact structure 140A can be used in addition to front contact structure 126 to provide electrical signals from a power rail to gate structure 112, according to some embodiments. In some embodiments, front contact structure 126 may be absent in semiconductor device 100 and back contact structure 140A can be used in place of front contact structure 126 to provide electrical signals from a power rail to gate structure 112.

Referring to FIGS. 1B-1D, back contact structure 140A can be disposed on a back surface of gate structure 112 and on a back surface and sidewalls of isolation structure 111. In some embodiments, back contact structure 140A can have a U-shaped cross-sectional profile along a YZ-plane, as shown in FIG. 1D, and a tapered cross-sectional profile along an XZ-plane, as shown in FIGS. 1B and 1C. In some embodiments, a top surface of back contact structure 140A can be in contact with back surfaces of nWFM layer 130N and pWFM layer 130P and a back surface of back contact structure 140A can be substantially coplanar with a back surface 104b of substrate 104. By forming back contact structure 140A on the back surface of gate structure 112, back contact structure 140A can be formed with (i) a larger volume compared to front contact structure 126, and (ii) a larger contact area with gate structure 112 compared to contact area between front contact structure 126 and gate structure 112. As a result, (i) gate structure 112 can have lower gate resistance compared to gate structure without back contact structure 140A, and (ii) gate structure 112 can have a lower contact resistance between gate structure 112 and back contact structure 140A compared to contact resistance between gate structure 112 and front contact structure 126.

Referring to FIGS. 1B-1D, in some embodiments, back contact structure 140A can include (i) a conductive layer 142A, (ii) an outer dielectric liner 144A, and (iii) an inner dielectric liner 146A (not visible in FIGS. 1B and 1C). In some embodiments, conductive layer 142A can include a conductive material, such as W, Ru, Al, Mo, Ir, Ni, Os, other suitable conductive materials, and a combination thereof. In some embodiments, conductive layer 142A can have (i) a U-shaped cross-sectional profile along a YZ-plane, as shown in FIG. 1D, (ii) a tapered cross-sectional profile along an XZ-plane, as shown in FIGS. 1B and 1C, (iii) a top surface portion 142At1 in contact with the back surface of nWFM layer 130N, (iv) a top surface portion 142At2 in contact with the back surface of pWFM layer 130P, (v) a top surface portion 142At3 in contact with the back surface of isolation structure 111, (vi) a back surface 142As substantially coplanar with a back surface 104b of substrate 104, (vii) top surface portion 142At1 substantially coplanar with or above the back surface of nWFM layer 130N, and (viii) top surface portion 142At2 substantially coplanar with or above the back surface of pWFM layer 130P.

In some embodiments, outer dielectric liner 144A and inner dielectric liner 146A can include SiN layers. In some embodiments, outer dielectric liner 144A can (i) surround the outer surface of conductive layer 142A, (ii) have a top surface in contact with the back surfaces of nWFM layer 130N and pWFM layer 130P, (iii) have a back surface substantially coplanar with back surface 142As of conductive layer 142A and back surface 104b of substrate 104, and (iv) be in contact with sidewalls of STI regions 105 and substrate 104 that faces isolation structure 111. In some embodiments, inner dielectric liner 146A can be in contact with the inner surface of conductive layer 142A and in contact with sidewalls of the portion of isolation structure 111 extending below the top surface of STI regions 105. In some embodiments, top surfaces of outer dielectric liner 144A and inner dielectric liner 146A can be substantially coplanar with each other and with top surface portions 142At1 and 142At2.

Referring to FIG. 1E, in some embodiments, semiconductor device 100 can have back contact structure 140B, instead of back contact structure 140A. The discussion of back contact structure 140A applies to back contact structure 140B, unless mentioned otherwise. The cross-sectional views of back contact structure 140B along lines A-A and B-B of FIG. 1A can be the same as the cross-sectional views of back contact structure 140A shown in FIGS. 1B and 1C. Back contact structure 140B can be disposed on the back surface of gate structure 112 and on the back surface of a recessed portion of isolation structure 111. In some embodiments, back contact structure 140A can include (i) a conductive layer 142B and (ii) a dielectric liner 144B surrounding conductive layer 142B. In some embodiments, conductive layer 142A can include a conductive material, such as W, Ru, Al, Mo, Ir, Ni, Os, other suitable conductive materials, and a combination thereof and dielectric liner 142B can include a SiN layer. The discussion of outer dielectric liner 144A applies to dielectric liner 142B, unless mentioned otherwise.

In some embodiments, conductive layer 142B can have (i) a top surface portion 142Bt1 in contact with the back surface of nWFM layer 130N, (ii) a top surface portion 142Bt2 in contact with the back surface of pWFM layer 130P, (iii) top surface portion 142Bt1 substantially coplanar with or above the back surface of nWFM layer 130N, (iv) top surface portion 142Bt2 substantially coplanar with or above the back surface of pWFM layer 130P, and (v) a back surface 142Bs substantially coplanar with back surface 104b of substrate 104. In some embodiments, conductive layer 142B further includes a protruding portion 142Bp, which extends laterally under nanostructured channel regions 108N and 108P. In some embodiments, protruding portion 142Bp can have (i) a top surface in contact with the back surface of the recessed portion of isolation structure 111, (ii) the top surface at a higher level than top surfaces 142Bt1 and 142Bt2 and the top surface of dielectric liner 144B, (iii) the top surface separated from the bottommost nanostructured channel regions 108N and 108P by IL layers 127 and HK gate dielectric layer 128, (iv) a first sidewall in contact with a sidewall of nWFM layer 130N, (v) a second sidewall in contact with a sidewall of pWFM layer 130P, (vi) the first sidewall under nanostructured channel regions 108N, (vii) the second sidewall under nanostructured channel regions 108P, and (viii) a width greater than a width of isolation structure along a Y-axis.

With the use of conductive layer 142B having protruding portion 142Bp, back contact structure 140B can have (i) a larger volume compared to back contact structure 140A, and (ii) a larger contact area with gate structure 112 compared to contact area between back contact structure 140A and gate structure 112. As a result, (i) gate structure 112 can have lower gate resistance compared to gate structure 112 with back contact structure 140A, and (ii) gate structure 112 can have a lower contact resistance between gate structure 112 and back contact structure 140B compared to contact resistance between gate structure 112 and back contact structure 140A. In some embodiments, conductive layer 142B may not have protruding portion 142Bp and instead, conductive layer 142B can have a substantially planar top surface and a rectangular cross-sectional profile along a YZ-plane.

Referring to FIG. 1F, in some embodiments, semiconductor device 100 can have back contact structures 140C and 140D, instead of back contact structures 140A and 140B. The discussion of back contact structure 140A applies to back contact structures 140C and 140D, unless mentioned otherwise. The cross-sectional view of back contact structure 140C along line A-A of FIG. 1A can be the same as the cross-sectional view of back contact structure 140A shown in FIG. 1B and the cross-sectional view of back contact structure 140D along line B-B of FIG. 1A can be the same as the cross-sectional view of back contact structure 140A shown in FIG. 1C. Back contact structures 140C and 140D are not disposed on back surface of isolation structure 111 and are not shared by both NFET 102N and PFET 102P. Back contact structure 140C can be used to individually control NFET 102N through gate structure 112 and back contact structure 140D can be used to individually control PFET 102P through gate structure 112.

Back contact structure 140C can be disposed on the back surface of nWFM layer 130N and along a sidewall of isolation structure 111 that faces nanostructured channel regions 108N. Back contact structure 140D can be disposed on the back surface of pWFM layer 130P and along a sidewall of isolation structure 111 that faces nanostructured channel regions 108P. In some embodiments, back contact structure 140C can include (i) a conductive layer 142C and (ii) a dielectric liner 144C surrounding conductive layer 142C and back contact structure 140D can include (i) a conductive layer 142D and (ii) a dielectric liner 144D surrounding conductive layer 142D. In some embodiments, conductive layers 142C and 142D can include the same conductive material, such as W, Ru, Al, Mo, Ir, Ni, Os, other suitable conductive materials. In some embodiments, dielectric liners 144C and 144D can include SiN layers.

In some embodiments, conductive layer 142C can have (i) a top surface 142Ct in contact with the back surface of nWFM layer 130N, (ii) top surface 142Ct substantially coplanar with or above the back surface of nWFM layer 130N, and (iii) a back surface 142Cs substantially coplanar with back surface 104b of substrate 104. In some embodiments, conductive layer 142D can have (i) a top surface 142Dt in contact with the back surface of pWFM layer 130P, (ii) top surface 142Dt substantially coplanar with or above the back surface of pWFM layer 130P, and (iii) a back surface 142Ds substantially coplanar with back surface 104b of substrate 104. In some embodiments, dielectric liner 144C can have (i) a sidewall in contact with and substantially coplanar with the sidewall of isolation structure 111 that faces nanostructured channel regions 108N, (ii) the sidewall substantially coplanar with sidewalls of nanostructure channel regions 108N in contact with isolation structure 111, (iii) a top surface substantially coplanar with top surface 142Ct, and (iv) a back surface substantially coplanar with back surface 142Cs and back surface 104b of substrate 104. In some embodiments, dielectric liner 144D can have (i) a sidewall in contact with and substantially coplanar with the sidewall of isolation structure 111 that faces nanostructured channel regions 108P, (ii) the sidewall substantially coplanar with sidewalls of nanostructure channel regions 108P in contact with isolation structure 111, (iii) a top surface substantially coplanar with top surface 142Dt, and (iv) a back surface substantially coplanar with back surface 142Ds and back surface 104b of substrate 104.

Referring to FIG. 1G, in some embodiments, semiconductor device 100 can have back contact structures 140E and 140F, instead of back contact structures 140C and 140D. The discussion of back contact structures 140C and 140D applies to back contact structures 140C and 140D, respectively, unless mentioned otherwise. Back contact structures 140E and 140F extend laterally into isolation structure 111. In some embodiments, back contact structure 140E can include (i) a conductive layer 142E and (ii) a dielectric liner 144E surrounding conductive layer 142E and back contact structure 140F can include (i) a conductive layer 142F and (ii) a dielectric liner 144F surrounding conductive layer 142F. The discussion of conductive layers 142C and 142D applies to conductive layers 142E and 142F, respectively, unless mentioned otherwise. The discussion of dielectric liners 144C and 144D applies to dielectric liners 144E and 144F, respectively, unless mentioned otherwise. In some embodiments, conductive layers 142E and 142F extend laterally into isolation structure 111 and widths of conductive layers 142E and 142F can be greater than widths of nanostructure channel regions 108N and 108P, respectively, along a Y-axis. In some embodiments, a sidewall of dielectric liner 144E can be non-coplanar with sidewalls of nanostructure channel regions 108N in contact with isolation structure 111 and a sidewall of dielectric liner 144F can be non-coplanar with sidewalls of nanostructure channel regions 108P in contact with isolation structure 111.

Referring to FIG. 1H, in some embodiments, semiconductor device 100 can have back contact structures 140G and 140H, instead of back contact structures 140E and 140F. The discussion of back contact structures 140E and 140F applies to back contact structures 140G and 140H, respectively, unless mentioned otherwise. Back contact structures 140E and 140F extend laterally into isolation structure 111. In some embodiments, back contact structure 140E can include (i) a conductive layer 142E and (ii) a dielectric liner 144E surrounding conductive layer 142E and back contact structure 140F can include (i) a conductive layer 142F and (ii) a dielectric liner 144F surrounding conductive layer 142F. The discussion of conductive layers 142C and 142D applies to conductive layers 142E and 142F, respectively, unless mentioned otherwise. The discussion of dielectric liners 144C and 144D applies to dielectric liners 144E and 144F, respectively, unless mentioned otherwise.

Conductive layer 142G can have a protruding portion 142Gp, which extends laterally under nanostructured channel regions 108N and into isolation structure 111. In some embodiments, protruding portion 142Gp can have (i) a top surface in contact with HK gate dielectric layer 128, and (ii) a sidewall in contact with a sidewall of nWFM layer 130N and under nanostructured channel regions 108N. In some embodiments, protruding portion 142Hp can have (i) a top surface in contact with HK gate dielectric layer 128, and (ii) a sidewall in contact with a sidewall of pWFM layer 130P and under nanostructured channel regions 108P. In some embodiments, top surfaces of portions of dielectric liners 144G and 144H facing isolation structure can be at a higher level that top surfaces of portions of dielectric liners 144G and 144H facing STI regions 105.

In some embodiments, semiconductor device 100 with back contact structure 140A or 140B can have the top view shown in FIG. 1I. In some embodiments, semiconductor device 100 with back contact structures 140C and 140D, 140E and 140F, or 140G and 140H can have the top view shown in FIG. 1J. In the top down views of FIGS. 1I and 1J, gate metal layer 132, HK gate dielectric layer 128, ILD layers 120A and 120B, ESLs 118A and 118B, STI regions 105, and substrate 104 are not shown for simplicity.

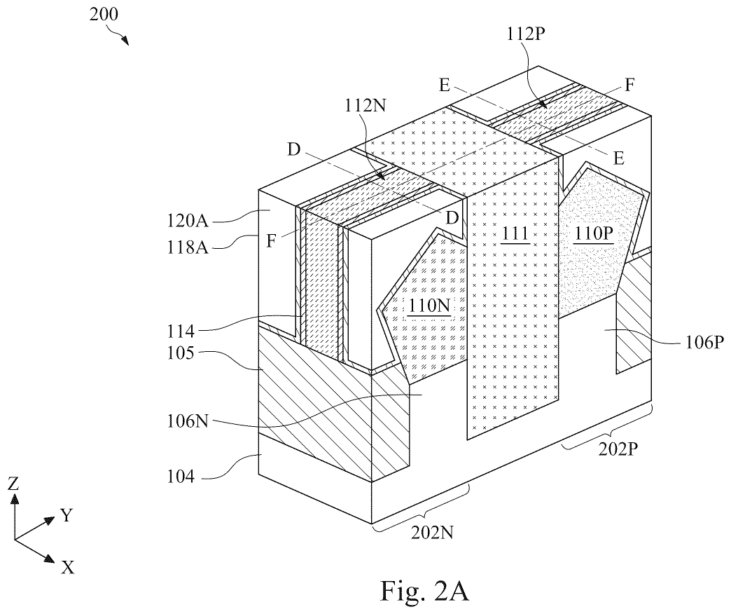

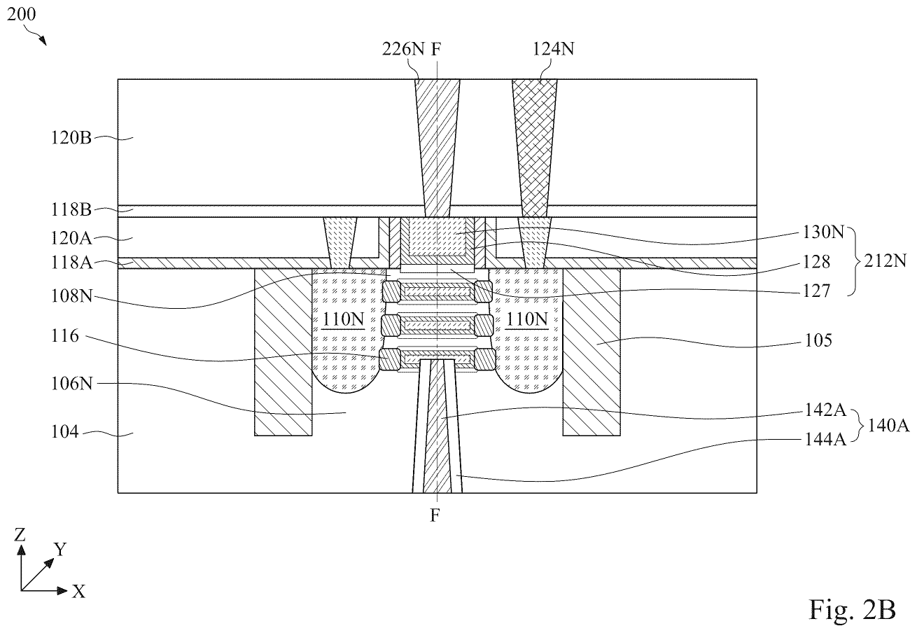

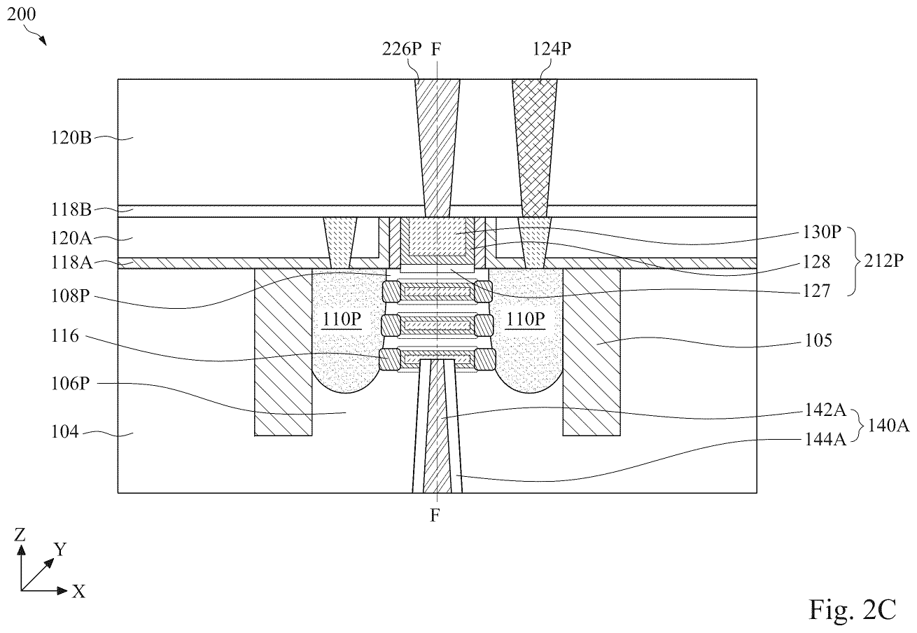

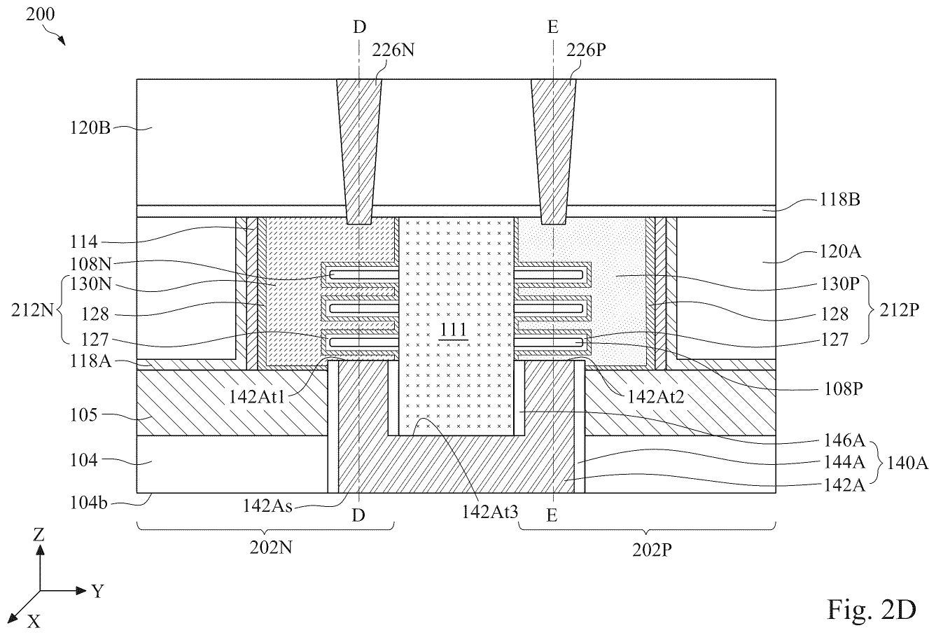

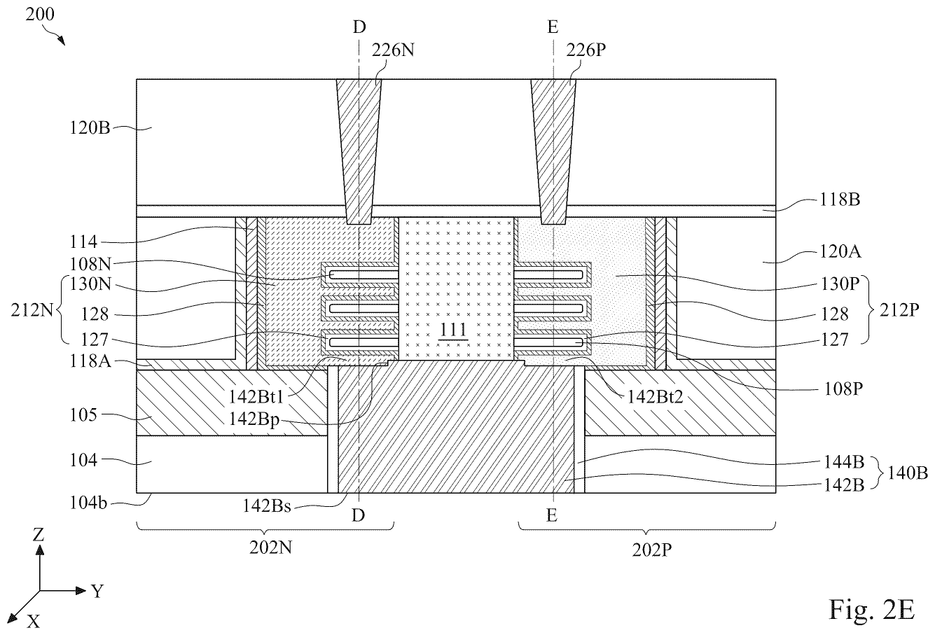

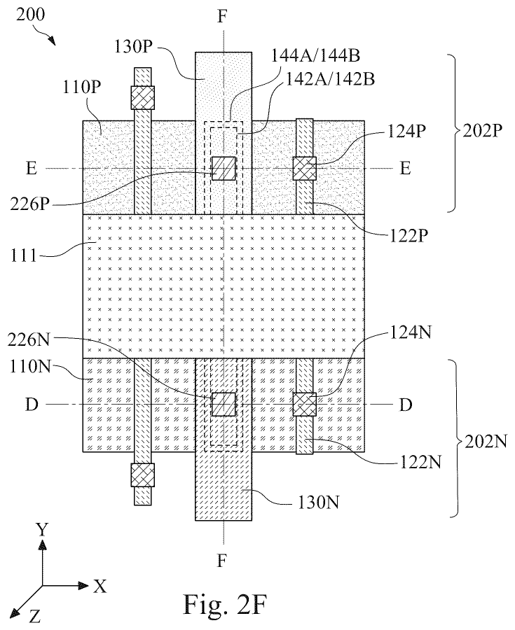

FIG. 2A illustrates an isometric view of a semiconductor device 200, according to some embodiments. The discussion of semiconductor device 100 applies to semiconductor device 200, unless mentioned otherwise. Semiconductor device can include an NFET 202N and a PFET 202P, according to some embodiments. The discussion of NFET 102N and PFET 102P applies to NFET 202N and PFET 202P, respectively, unless mentioned otherwise. FIG. 2B illustrates a cross-sectional view of semiconductor device 200 along line D-D of FIG. 2A and FIG. 2C illustrates a cross-sectional view of semiconductor device 200 along line E-E of FIG. 2A, according to some embodiments. FIGS. 2D and 2E illustrate different cross-sectional views of semiconductor device 200 along line F-F of FIG. 2A, according to some embodiments. FIG. 2F illustrates a top-down views of semiconductor device 200, according to some embodiments.

FIGS. 2B-2F illustrate views with additional structures that are not shown in FIG. 2A for simplicity. The discussion of elements in FIGS. 1A-1J and 2A-2F with the same annotations applies to each other, unless mentioned otherwise.

Semiconductor device 200 can include tungsten-free gate structures 212N and 212P, which are not shared by NFET 202N and PFET 202P. Gate structure 212N can be used to individually control NFET 202N and gate structure 212P can be used to individually control PFET 202P. Gate structures 212N and 212P may not include gate metal layer 132. In some embodiments, gate structure 212N can include (i) IL layer 127 on nanostructure channel regions 108N, (iii) HK gate dielectric layer 128, and (iii) nWFM layer 130N and gate structure 212P can include (i) IL layer 127 on nanostructured channel regions 108P, (iii) HK gate dielectric layer 128, and (iii) nWFM layer 130P. ESL 118B can be disposed directly on nWFM layer 130N, pWFM layer 130P, and isolation structure 111.

Semiconductor device 200 can include front contact structures 226N and 226P, which are not shared by both NFET 202N and PFET 202P. Front contact structure 226N can be used to individually provide signals to NFET 202N and front contact structure 226P can be used to individually provide signals to PFET 102P. The materials of front contact structures 226N and 226P can be the same as front contact structure 126 discussed above. In some embodiments, front contact structures 226N and 226P can be present in addition to back contact structure 140A (shown in FIG. 2D) or 140B (shown in FIG. 2E). In some embodiments, front contact structures 226N and 226P can be present in addition to back contact structure 140A (shown in FIG. 2D) or 140B (shown in FIG. 2E). In some embodiments, front contact structures 226N and 226P may be absent in semiconductor device 200 and back contact structure 140A or 140B can be used to provide electrical signals from a power rail to both gate structures 212N and 212P. In some embodiments, semiconductor device 200 with back contact structure 140A or 140B can have the top view shown in FIG. 2F. In the top down view of FIG. 2F, HK gate dielectric layer 128, ILD layers 120A and 120B, ESLs 118A and 118B, STI regions 105, and substrate 104 are not shown for simplicity.

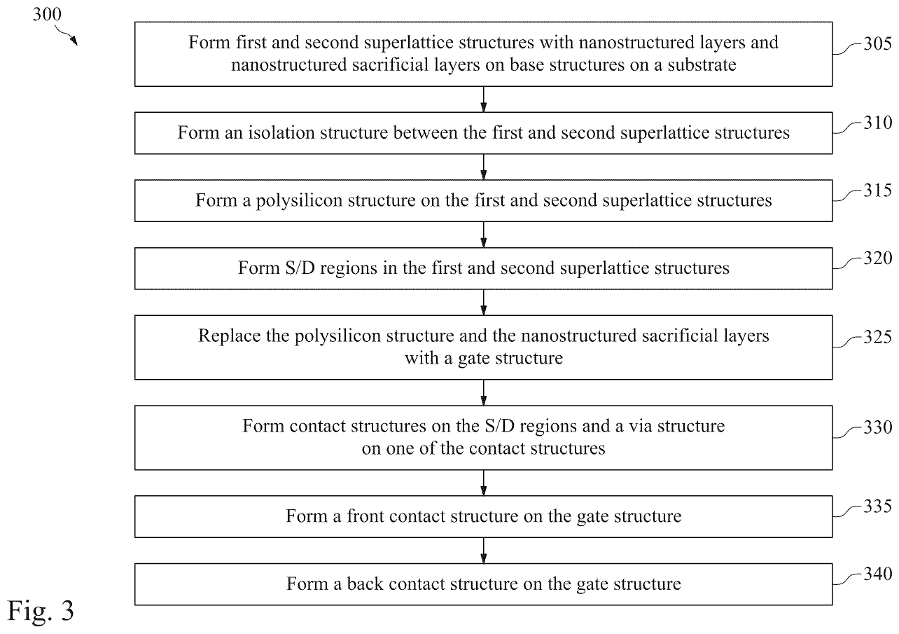

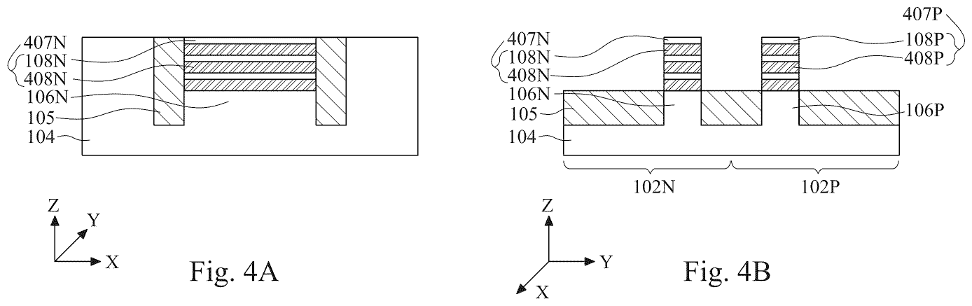

FIG. 3 is a flow diagram of an example method 300 for fabricating semiconductor device 100 with the cross-sectional views of FIGS. 1B-1D, according to some embodiments. For illustrative purposes, the operations illustrated in FIG. 3 will be described with reference to the example fabrication process for fabricating semiconductor device 100 as illustrated in FIGS. 4A-21A and 4B-21B. FIGS. 4A-21A are cross-sectional views of semiconductor device 100 along line A-A of FIG. 1A and FIGS. 4B-21B are cross-sectional views of semiconductor device 100 along line C-C of FIG. 1A at various stages of fabrication of semiconductor device 100, according to some embodiments. Operations can be performed in a different order or not performed depending on specific applications. It should be noted that method 300 may not produce a complete semiconductor device 100. Accordingly, it is understood that additional processes can be provided before, during, and after method 300, and that some other processes may only be briefly described herein. The discussion of elements in FIGS. 1A-1D, 11, 4A-21A and 4B-21B with the same annotations applies to each other, unless mentioned otherwise.

Referring to FIG. 3, in operation 305, first and second superlattice structures with nanostructured layers and nanostructured sacrificial layers are formed on base structures on a substrate. For example, as described with reference to FIGS. 4A and 4B, first superlattice structure 407N (also referred to as “first nanosheet stack 407N”) is formed on base structure 106N and second superlattice structure 407P (also referred to as “second nanosheet stack 407P”) is formed on base structure 106P, which are formed on substrate 104. First superlattice structure 407N can include nanostructured layers 108N and nanostructured sacrificial layers 408N arranged in an alternating configuration. Second superlattice structure 407P can include nanostructured layers 108P and nanostructured sacrificial layers 408P arranged in an alternating configuration. In some embodiments, nanostructured layers 108N and 108P can include Si and nanostructured sacrificial layers 408N and 408P can include SiGe. The formation of first and second superlattice structures 407N and 407P can be followed by the formation of STI regions 105.

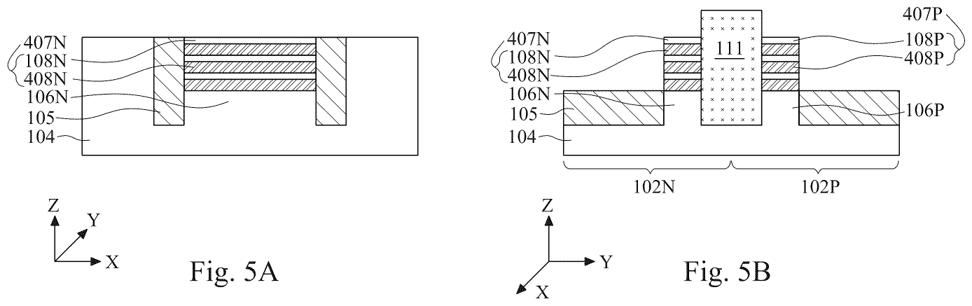

Referring to FIG. 3, in operation 310, an isolation structure is formed between the first and second superlattice structures. For example, as shown in FIG. 5B, isolation structure 111 is formed between first and second superlattice structures 407N and 407P and on substrate 104. Isolation structure 111 is not visible in cross-sectional view of FIG. 5A. The formation of isolation structure 111 can include depositing a dielectric layer (not shown) on the structures of FIGS. 4A and 4B and patterning the dielectric layer using photolithographic and etching processes.

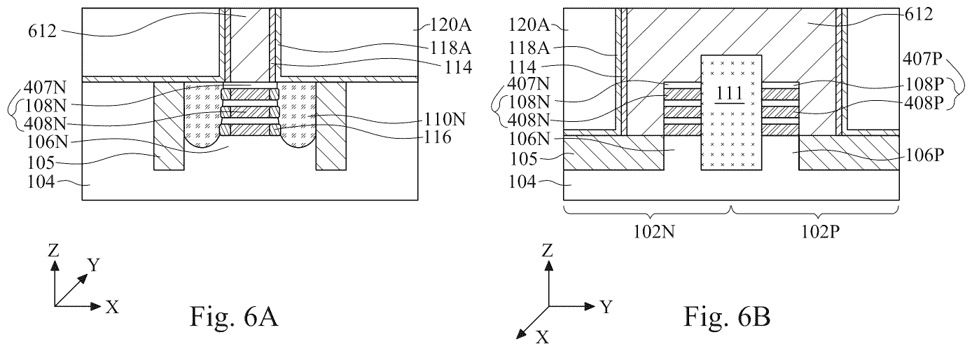

Referring to FIG. 3, in operation 315, a polysilicon structure is formed on the first and second superlattice structures. For example, as described with reference to FIGS. 6A and 6B, polysilicon structures 612 is formed on first and second superlattice structures 407N and 407P. During subsequent processing, polysilicon structure 612 and nanostructured sacrificial layers 408N and 408P can be replaced with gate structure 212 in a gate replacement process.

Referring to FIG. 3, in operation 320, S/D regions are formed in the first and second superlattice structures. For example, as described with reference to FIGS. 6A and 6B, S/D regions 110N are formed in first superlattice structure 407N, and S/D regions 110P (as shown in FIGS. 1A and 1C; not visible in the cross-sectional views of FIGS. 6A and 6B) are formed in second superlattice structure 407P. The formation of S/D regions 110N and 110P can be followed by the formation of ESLs 118A and ILD layers 120A, as shown in FIGS. 6A and 6B.

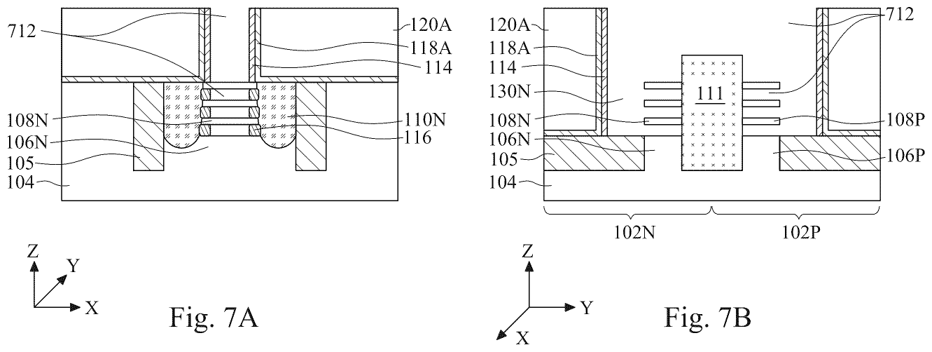

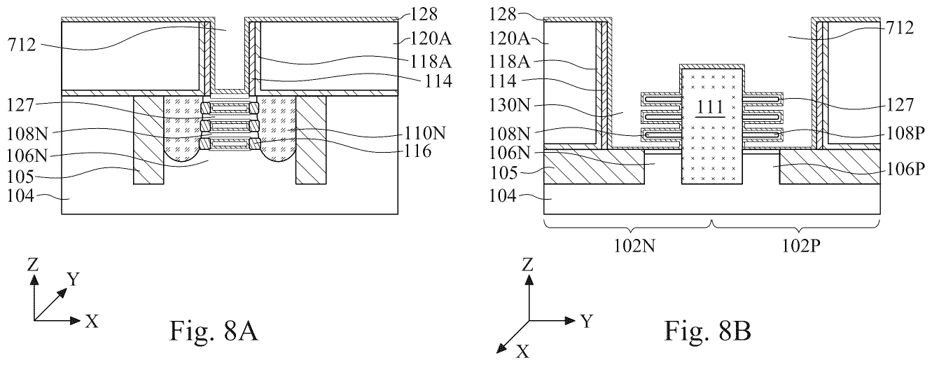

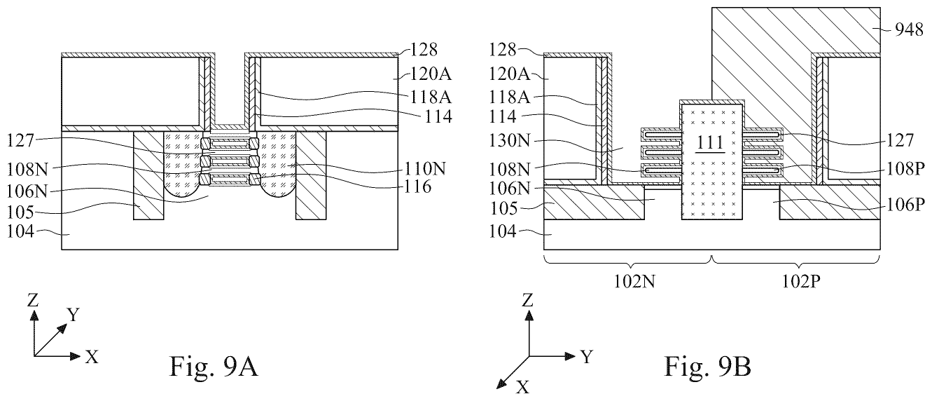

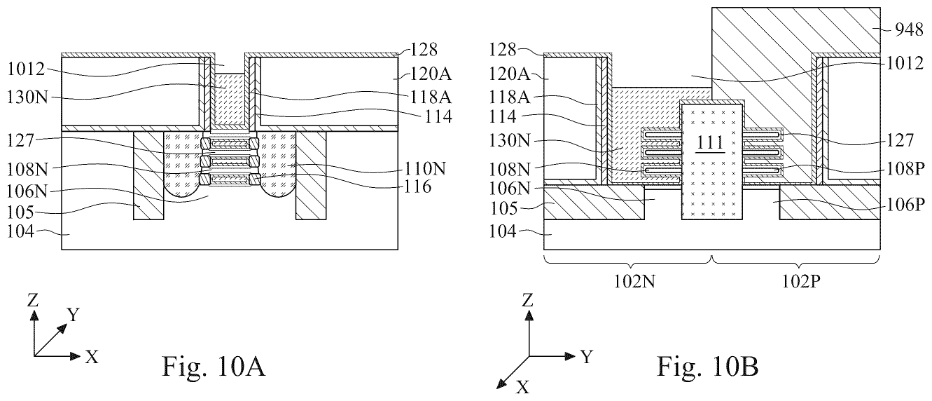

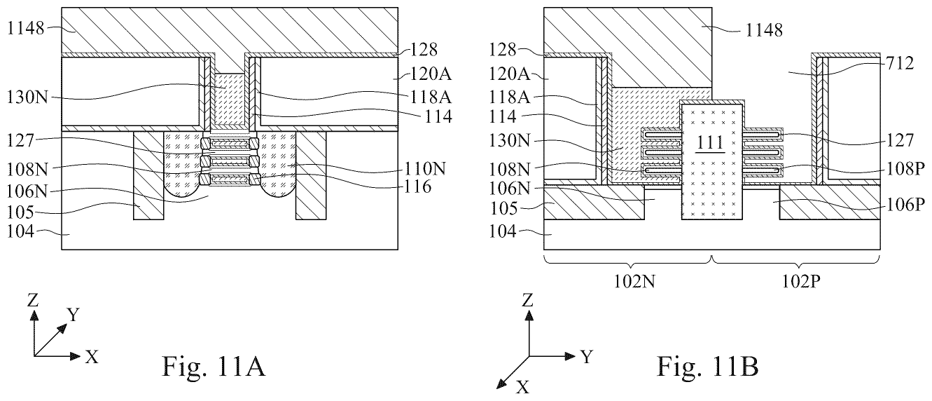

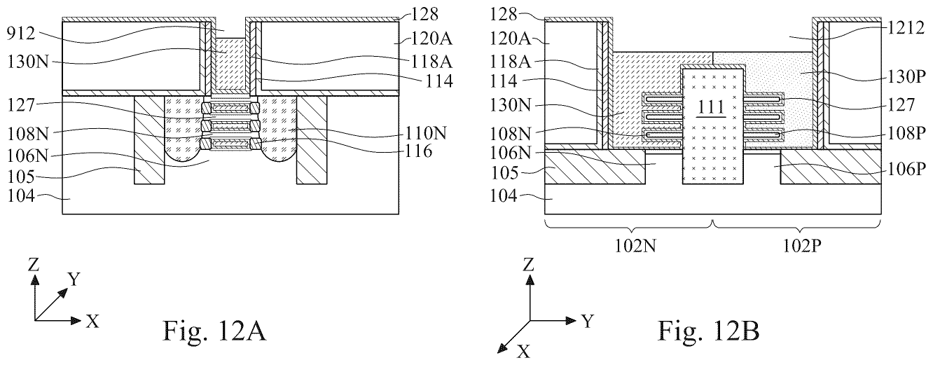

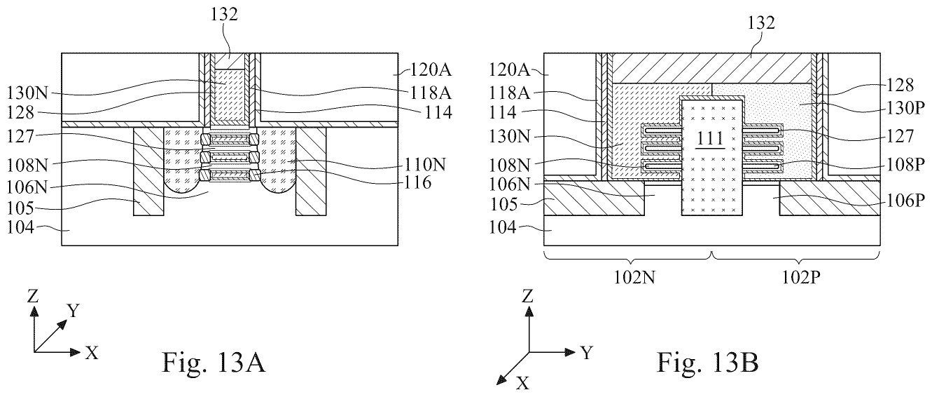

Referring to FIG. 3, in operation 325, the polysilicon structure and the nanostructured sacrificial layers are replaced with a gate structure. For example, as described with reference to FIGS. 7A-13A and 7B-13B, polysilicon structure 612 and nanostructured sacrificial layers 408N and 408P are replaced with gate structure 112 in a gate replacement process. The gate replacement process can include sequential operations of (i) removing (e.g., etching) polysilicon structure 612 and nanostructured sacrificial layers 408N and 408P to form gate openings 712, as shown in FIGS. 7A and 7B, (ii) performing an oxidation process on the exposed surfaces of nanostructured channel regions 108N and 108P in gate openings 712 to form IL layers 127, as shown in FIGS. 8A and 8B, (iii) depositing a HK gate dielectric layer 128 on exposed surfaces of IL layers 127, isolation structure 111, outer gate spacers 114, ESLs 118A, and ILD layer 120A, as shown in FIGS. 8A and 8B, (iv) forming a patterned masking layer 948 (e.g., a photoresist layer) to cover the elements in PFET 102P area using photolithographic and etching processes, as shown in FIG. 9B (patterned masking layer 948 not visible in cross-sectional view of FIG. 9A), (v) depositing nWFM layer 130N on the structures of FIGS. 9A and 9B to fill (not shown) gate openings 712, (vi) etching nWFM layer 130N to form gate opening 1012 on nWFM layer 130N, as shown in FIGS. 10A and 10B, (vii) removing patterned masking layer 948, (viii) forming a patterned masking layer 1148 (e.g., a photoresist layer) to cover the elements in NFET 102N area using photolithographic and etching processes, as shown in FIGS. 11A and 11B, (ix) depositing pWFM layer 130P on the structures of FIGS. 11A and 11B to fill (not shown) gate opening 712, (x) etching pWFM layer 130P to form gate opening 1212 on pWFM layer 130P, as shown in FIG. 12B (pWFM layer 130P not visible in the cross-sectional view of FIG. 12A), (xi) removing patterned masking layer 1148 to form the structures of FIGS. 12A and 12B, (xii) depositing gate metal layer 132 on the structure of FIGS. 12A and 12B to fill gate openings 912 and 1212, and (xiii) performing a CMP process on gate metal layer 132 to coplanarize top surfaces of gate metal layer 132, HK gate dielectric layer 128, outer gate spacers 114, ESLs 118A, and ILD layers 120A, as shown in FIGS. 13A and 13B.

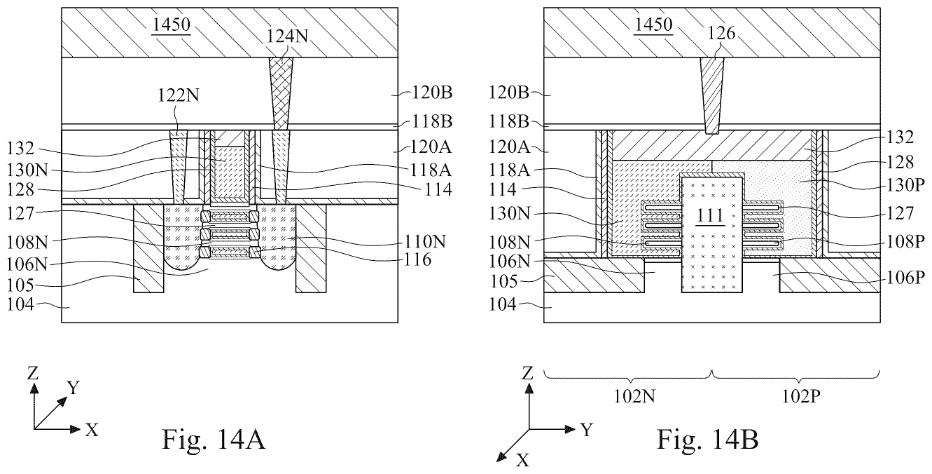

Referring to FIG. 3, in operation 330, contact structures are formed on the S/D regions and a via structure is formed on one of the contact structures. For example, as described with reference to FIG. 14A, contact structures 122N are formed on S/D regions 110N (not visible in the cross-sectional view of FIG. 14B) and contact structures 122P are formed on S/D regions 110P (as shown in FIG. 1C; not visible in the cross-sectional views of FIGS. 14A and 14B). The formation of contact structures 122N and 122P can include sequential operations of (i) forming contact openings (not shown) in ILD layers 120A and ESLs 118A, (ii) depositing a conductive material (not shown) in the contact openings, and (iii) performing a CMP process on the conductive material to coplanarize top surfaces of the conductive material, ILD layers 120A, ESLs 118A, outer gate spacers 114, HK gate dielectric layer 128, and gate metal layer 132, as shown in FIG. 14A. The formation of contact structures 122N and 122P can be followed by the formation of ESLs 118B and ILD layers 120B, as shown in FIGS. 14A and 14B. The formation of ILD layers 120B can be followed by the formation of via structure 124N, as shown in FIG. 14A and via structure 124P (as shown in FIG. 1C; not visible in the cross-sectional views of FIGS. 14A and 14B). The formation of via structures 124N and 124P can include sequential operations of (i) forming via openings (not shown) in ILD layers 120B and ESLs 118B and on corresponding contact structures 122N and 122P, (ii) depositing a conductive material (not shown) in the via openings, and (iii) performing a CMP process on the conductive material to coplanarize top surfaces of the conductive material and ILD layers 120B, as shown in FIG. 14A.

Referring to FIG. 3, in operation 335, a front contact structure is formed on the gate structure. For example, as described with reference to FIG. 14B, front contact structure 126 is formed on the front surface of gate structure 112. Front contact structure 126 is not visible in the cross-sectional view of FIG. 14A. The formation of front contact structure 126 can include sequential operations of (i) forming a contact opening (not shown) in ILD layers 120B and ESLs 118B and on gate metal layer 132, (ii) depositing a conductive material (not shown) in the contact opening, and (iii) performing a CMP process on the conductive material to coplanarize top surfaces of front contact structure 126 and ILD layers 120B, as shown in FIG. 14B.

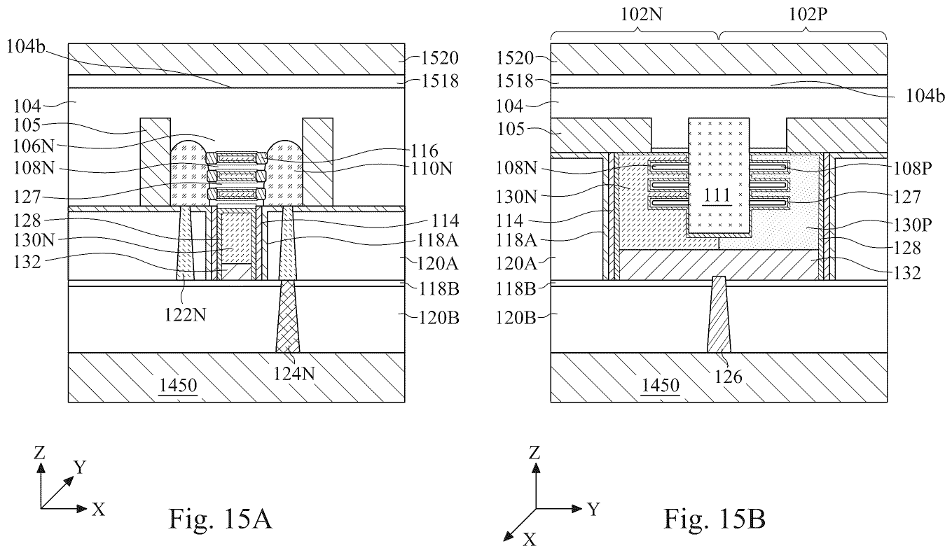

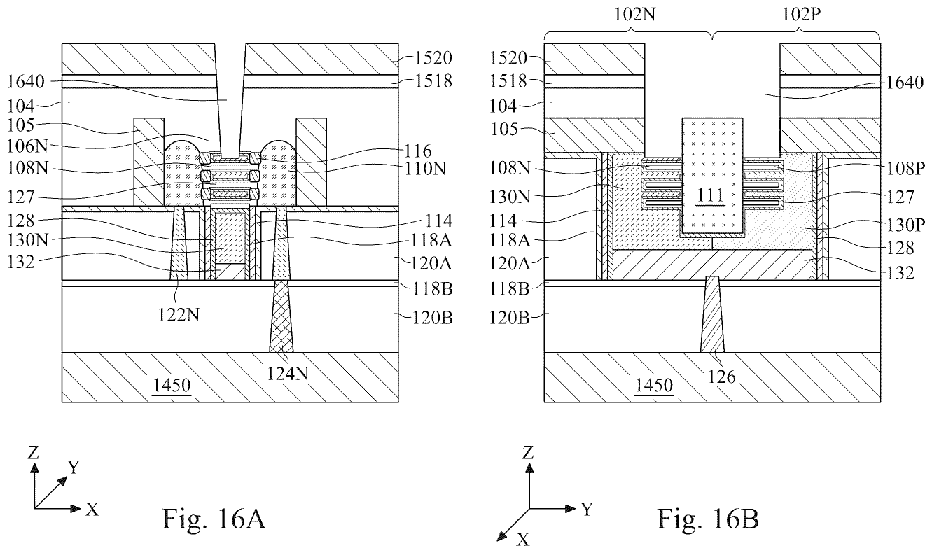

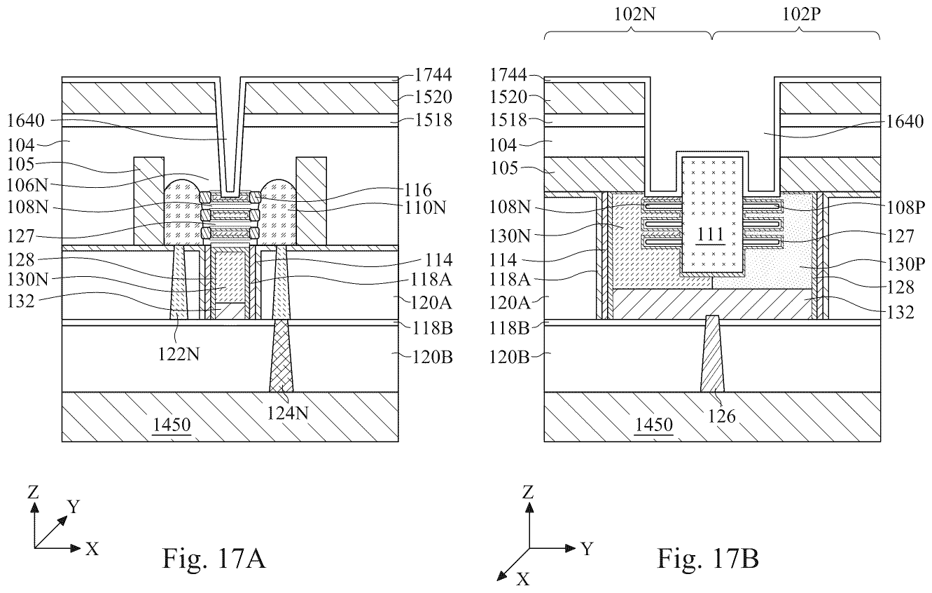

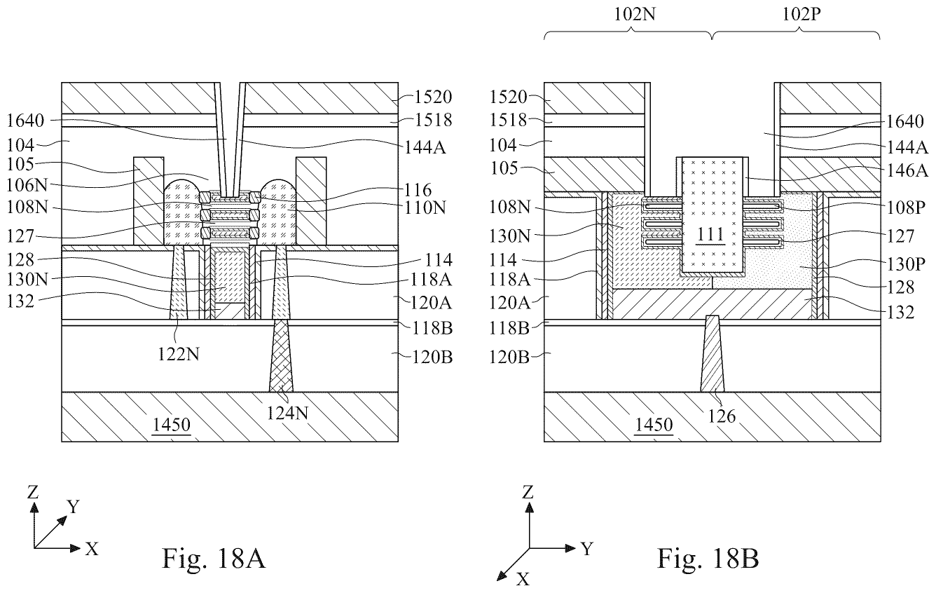

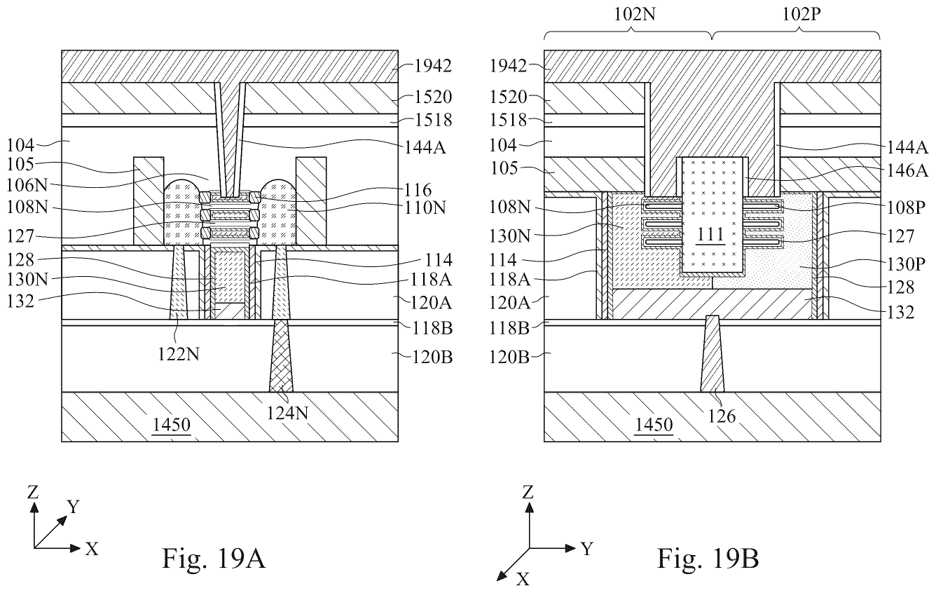

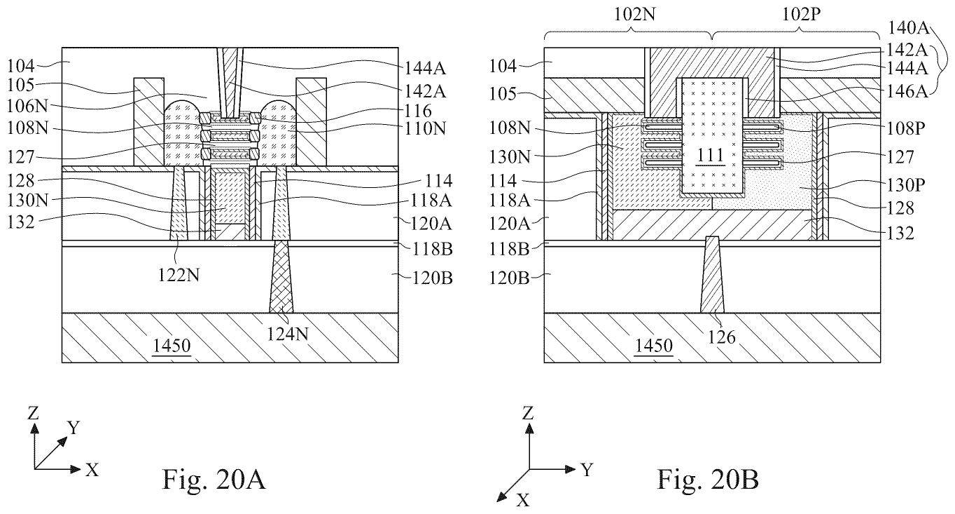

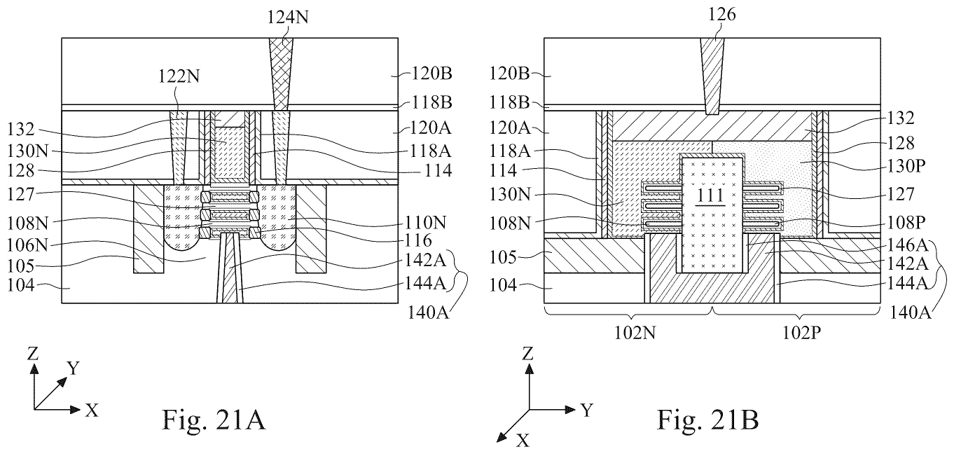

Referring to FIG. 3, in operation 340, a back contact structure is formed on the gate structure. For example, as described with reference to FIGS. 14A-21A and 14B-21B, back contact structure 140A is formed on the back surface of gate structure 112. The formation of back contact structure 140A can include sequential operations of (i) bonding a carrier substrate 1450 to top surfaces of ILD layers 120B, via structure 124N, and front contact structure 126, as shown in FIGS. 14A and 14B, (ii) performing a CMP process on back surface 104b of substrate 104 to thin down substrate 104, (iii) depositing an ESL 1518 having a dielectric material on back surface 104b of substrate 104, as shown in FIGS. 15A and 15B, (iv) depositing an ILD layer 1520 having a dielectric material on ESL 1518, as shown in FIGS. 15A and 15B, (v) etching portions of ILD layer 1520, ESL 1518, substrate 104, and base structures 106N and 106P to form a contact opening 1640 on back surfaces of nWFM layer 130N, pWFM layer 130P, and isolation structure 111, as shown in FIGS. 16A and 16B, (vi) depositing a nitride layer 1744 (e.g., a SiN layer) on exposed sidewalls of isolation structure 111 in contact opening 1640, on exposed back surfaces of nWFM layer 130N, pWFM layer 130P, and isolation structure 111 in contact opening 1640, and on top surface of ILD layer 1520, as shown in FIGS. 17A and 17B, (vii) performing an anisotropic etch (e.g., a plasma directional etch) on nitride layer 1744 to etch horizontal portions of nitride layer 1744 from back surfaces of nWFM layer 130N, pWFM layer 130P, and isolation structure 111 and from top surface of ILD layer 1520 to form outer and inner dielectric liners 144A and 146A, as shown in FIGS. 18A and 18B, (viii) depositing a conductive layer 1942 on outer and inner dielectric liners 144A and 146A and to fill contact opening 1640, as shown in FIGS. 19A and 19B, (ix) performing a CMP process on conductive layer 1942, ILD layer 1520, and ESL 1518 to coplanarize back surfaces of conductive layer 142A, outer dielectric liner 144A, and back surface 104b of substrate 104, as shown in FIGS. 20A and 20B, and (x) removing carrier substrate 1450 to form the structures of FIGS. 21A and 21B.

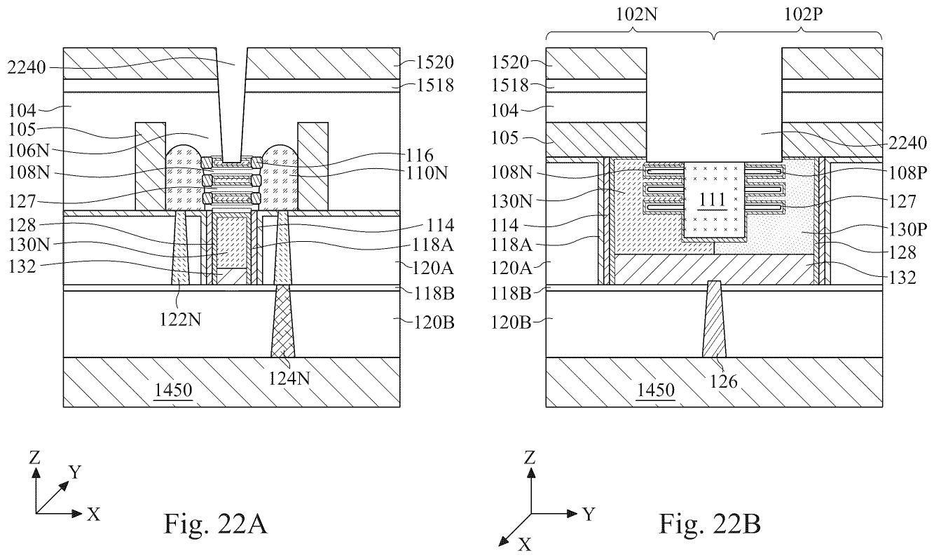

In some embodiments, referring to FIG. 3, in operation 340, back contact structure 140B is formed as described with reference to FIGS. 14A-16A, 14B-16B, 22A-25A, and 22B-25B, instead of back contact structure 140A as described with reference to FIGS. 14A-21A and 14B-21B. FIGS. 14A-16A, 14B-16B, 22A-25A, and 22B-25B illustrate the formation of semiconductor device 100 with the cross-sectional views of FIGS. 1B, 1C, and 1E, according to some embodiments. FIGS. 22A-25A are cross-sectional views of semiconductor device 100 along line A-A of FIG. 1A and FIGS. 22B-25B are cross-sectional views of semiconductor device 100 along line C-C of FIG. 1A at various stages of fabrication of semiconductor device 100, according to some embodiments. The discussion of elements in FIGS. 1A-1E, 11, 4A-25A, and 4B-25B with the same annotations applies to each other, unless mentioned otherwise.

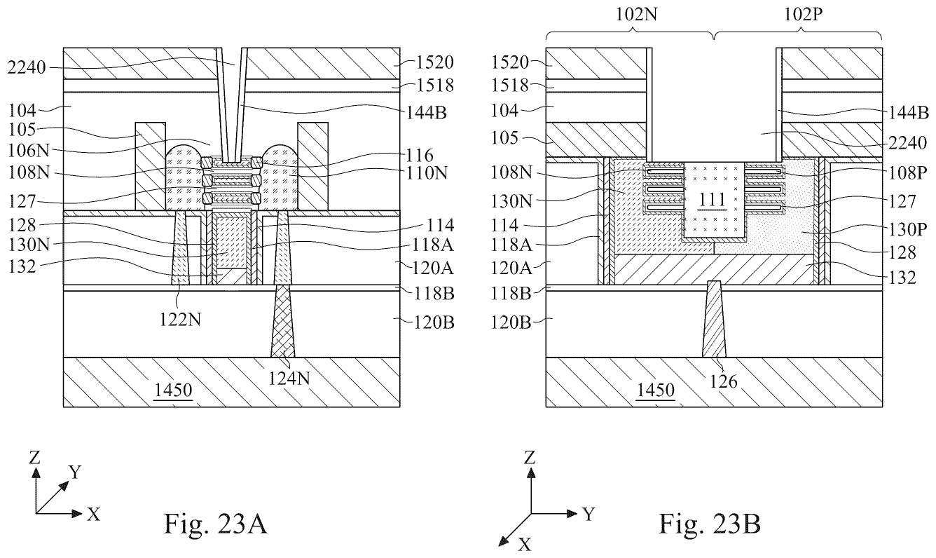

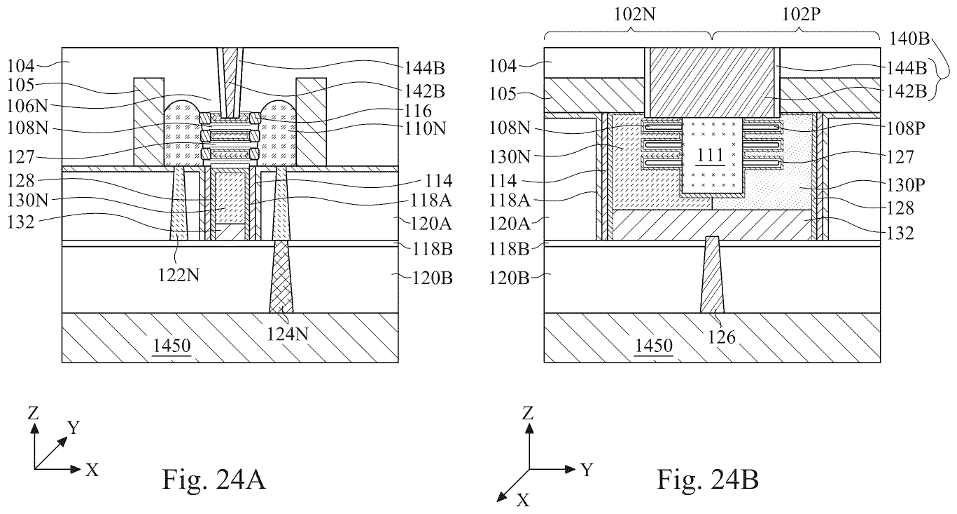

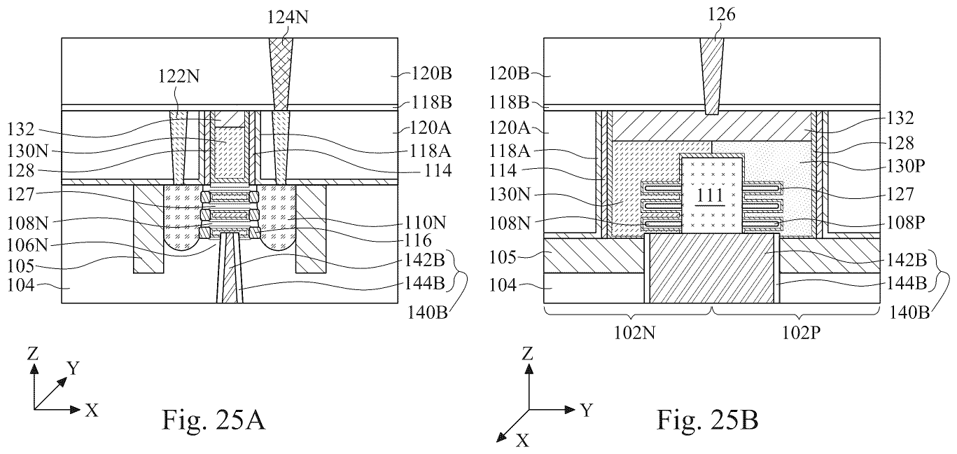

The formation of back contact structure 140B can include sequential operations of (i) bonding a carrier substrate 1450 to top surfaces of ILD layers 120B, via structure 124N, and front contact structure 126, as shown in FIGS. 14A and 14B, (ii) performing a CMP process on back surface 104b of substrate 104 to thin down substrate 104, (iii) depositing an ESL 1518 having a dielectric material on back surface 104b of substrate 104, as shown in FIGS. 15A and 15B, (iv) depositing an ILD layer 1520 having a dielectric material on ESL 1518, as shown in FIGS. 15A and 15B, (v) etching portions of ILD layer 1520, ESL 1518, substrate 104, and base structures 106N and 106P to form a contact opening 1640 on back surfaces of nWFM layer 130N, pWFM layer 130P, and isolation structure 111, as shown in FIGS. 16A and 16B, (vi) etching extended portion of isolation layer 111 in contact opening 1640 to lower back surface of isolation structure 111 below back surfaces of nWFM layer 130N and pWFM layer 130P and expose sidewalls of nWFM layer 130N and pWFM layer 130P and form contact opening 2240, as shown in FIGS. 22A and 22B, (vii) depositing a nitride layer (not shown, e.g., a SiN layer) on exposed sidewalls of nWFM layer 130N and pWFM layer 130P in contact opening 2240, on exposed back surfaces of nWFM layer 130N, pWFM layer 130P, and isolation structure 111 in contact opening 2240, and on top surface of ILD layer 1520, (viii) performing an anisotropic etch (e.g., a plasma directional etch) on the nitride layer to etch horizontal portions of the nitride layer to form dielectric liner 144B, as shown in FIGS. 23A and 23B, (ix) depositing a conductive layer (not shown) on dielectric liner 144B and to fill contact opening 2240, (x) performing a CMP process on the conductive layer, ILD layer 1520, and ESL 1518 to coplanarize back surfaces of conductive layer 142B, dielectric liner 144B, and back surface 104b of substrate 104, as shown in FIGS. 24A and 24B, and (xi) removing carrier substrate 1450 to form the structures of FIGS. 25A and 25B.

In some embodiments, operations (v) and (vi) above can be performed at the same time using a low-selectivity etch process to etch the extended portion of isolation layer 111 in contact opening 1640 and the portions of ILD layer 1520, ESL 1518, substrate 104, base structures 106N and 106P at the same time. In some embodiments, operations (v) and (vi) above can be performed in a two-step etch process. The first etch process can be performed in operation (v) using a low-selectivity etch process to etch the portions of ILD layer 1520, ESL 1518, substrate 104, base structures 106N and 106P. The first etch process can be followed by the second etch process, which can be performed in operation (vi) using a high-selectivity etch process to selectively etch the extended portion of isolation layer 111 in contact opening 1640.

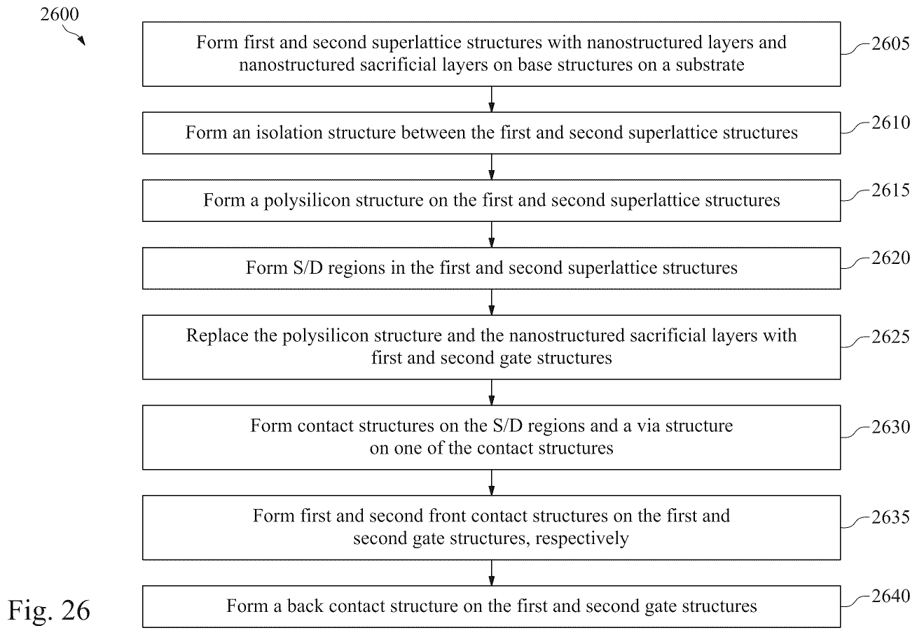

FIG. 26 is a flow diagram of an example method 2600 for fabricating semiconductor device 200 with the cross-sectional views of FIG. 2B-2D, according to some embodiments. For illustrative purposes, the operations illustrated in FIG. 26 will be described with reference to the example fabrication process for fabricating semiconductor device 200 as illustrated in FIGS. 4A-12A, 4B-12B, 27A-29A, 27B-29B, 14A-21A, and 14B-21B. FIGS. 4A-12A, 27A-29A, and 14A-21A are cross-sectional views of semiconductor device 200 along line D-D of FIG. 2A and FIGS. 4B-12B, 27B-29B, and 14B-21B are cross-sectional views of semiconductor device 200 along line F-F of FIG. 2A at various stages of fabrication of semiconductor device 200, according to some embodiments. Operations can be performed in a different order or not performed depending on specific applications. It should be noted that method 2600 may not produce a complete semiconductor device 300. Accordingly, it is understood that additional processes can be provided before, during, and after method 2600, and that some other processes may only be briefly described herein. The discussion of elements in FIGS. 2A-2D, 2F, 4A-12A, 4B-12B, 27A-29A, 27B-29B, 14A-21A, and 14B-21B with the same annotations applies to each other, unless mentioned otherwise.

Referring to FIG. 26, operations 2605-2620 are similar to operations 305-320 of FIG. 3. After operation 2620, a structures similar to structure of FIGS. 6A and 6B are formed.

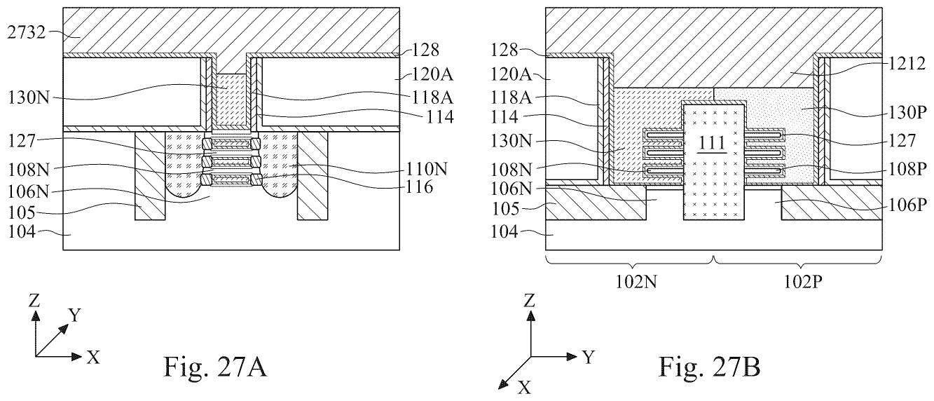

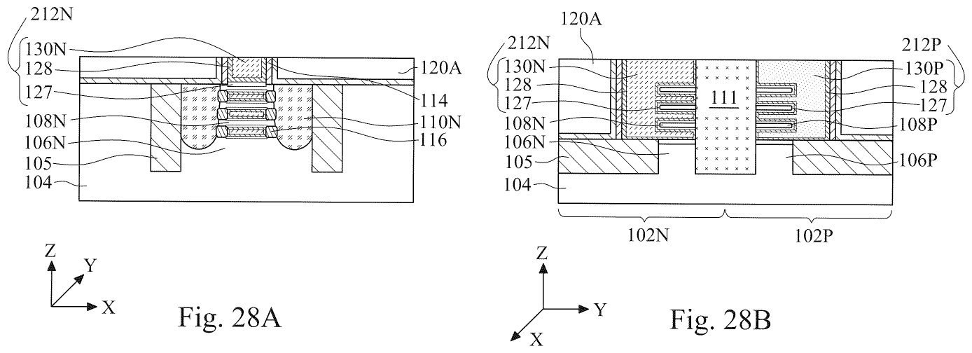

Referring to FIG. 26, in operation 2625, the polysilicon structure and the nanostructured sacrificial layers are replaced with first and second gate structures. For example, as described with reference to FIGS. 7A-12A, 7B-12B, 27A, 28A, 27B, and 28B polysilicon structure 612 and nanostructured sacrificial layers 408N and 408P are replaced with gate structures 212N and 212P in a gate replacement process. The gate replacement process can include sequential operations of (i) removing (e.g., etching) polysilicon structure 612 and nanostructured sacrificial layers 408N and 408P to form gate openings 712, as shown in FIGS. 7A and 7B, (ii) performing an oxidation process on the exposed surfaces of nanostructured channel regions 108N and 108P in gate openings 712 to form IL layers 127, as shown in FIGS. 8A and 8B, (iii) depositing a HK gate dielectric layer 128 on exposed surfaces of IL layers 127, isolation structure 111, outer gate spacers 114, ESLs 118A, and ILD layer 120A, as shown in FIGS. 8A and 8B, (iv) forming a patterned masking layer 948 (e.g., a photoresist layer) to cover the elements in PFET 102P area using photolithographic and etching processes, as shown in FIG. 9B (patterned masking layer 948 not visible in cross-sectional view of FIG. 9A), (v) depositing nWFM layer 130N on the structures of FIGS. 9A and 9B to fill (not shown) gate openings 712, (vi) etching nWFM layer 130N to form gate opening 1012 on nWFM layer 130N, as shown in FIGS. 10A and 10B, (vii) removing patterned masking layer 948, (viii) forming a patterned masking layer 1148 (e.g., a photoresist layer) to cover the elements in NFET 102N area using photolithographic and etching processes, as shown in FIGS. 11A and 11B, (ix) depositing pWFM layer 130P on the structures of FIGS. 11A and 11B to fill (not shown) gate opening 712, (x) etching pWFM layer 130P to form gate opening 1212 on pWFM layer 130P, as shown in FIG. 12B (pWFM layer 130P not visible in the cross-sectional view of FIG. 12A), (xi) removing patterned masking layer 1148 to form the structures of FIGS. 12A and 12B, (xii) depositing a metal layer 2732 on the structure of FIGS. 12A and 12B to fill gate openings 912 and 1212, as shown in FIGS. 27A and 27B, and (xiii) performing a CMP process on gate metal layer 132, ILD layers 120A, and ESLs 118A to coplanarize top surfaces of nWFM layer 130N, pWFM layer 130P, isolation structure 111, HK gate dielectric layer 128, outer gate spacers 114, ESLs 118A, and ILD layers 120A, as shown in FIGS. 28A and 28B.

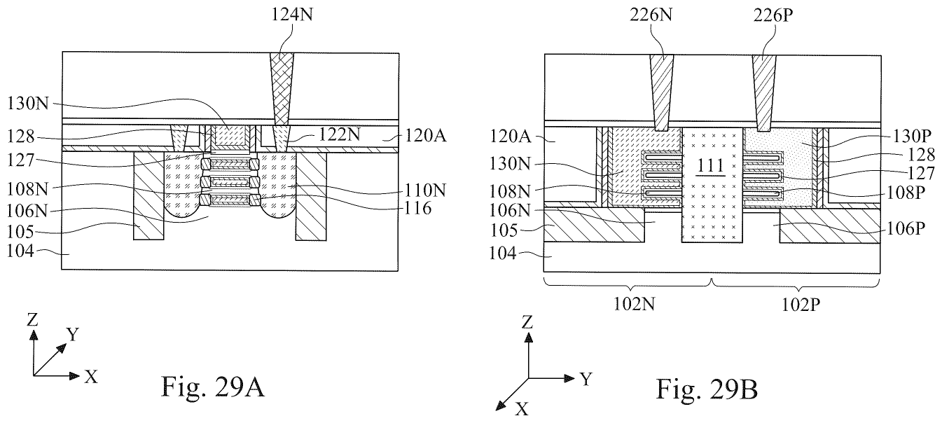

Referring to FIG. 26, operations 2630 is similar to operation 330 of FIG. 3. After operation 2630, contact structures 122N and via structure 124N are formed, as shown in FIG. 29A.

Referring to FIG. 26, in operation 2635, first and second front contact structures are formed on the first and second gate structures, respectively. For example, as described with reference to FIG. 29B, first and second front contact structures 226N and 226P are formed on first and second gate structures 212N and 212P, respectively. First and second front contact structures 226N and 226P are not visible in the cross-sectional view of FIG. 29A. The formation of first and second front contact structures 226N and 226P can include sequential operations of (i) forming contact openings (not shown) in ILD layers 120B and ESLs 118B and on nWFM layer 130N and pWFM layer 130P, (ii) depositing a conductive material (not shown) in the contact openings, and (iii) performing a CMP process on the conductive material to coplanarize top surfaces of front contact structures 226N and 226P and ILD layers 120B, as shown in FIG. 29B.

Referring to FIG. 26, operation 2640 is similar to operation 340 (described above with reference to FIGS. 14A-25A and 14B-25B), which can be performed on the back surfaces of the structures of FIGS. 29A and 29B to form back contact structure 140A or 140B on the back surfaces of nWFM layer 130 and pWFM layer 130, as shown in FIGS. 2B-2E.

The present disclosure provides example semiconductor devices (e.g., semiconductor devices 100 and 200) with back contact structures (e.g., back contact structures 140A-140H) on back surfaces of the gate structures (e.g., gate structures 112, 212N, and 212P) to improve reliability and performance of the semiconductor devices. The present disclosure also provides example methods (e.g., methods 300 and 2600) of forming such semiconductor devices. In some embodiments, the back contact structure (e.g., back contact structure 140A and 140B) can be disposed on and in contact with back surfaces of the nWFM layer (e.g., nWFM layer 130N) and the pWFM layer (e.g., pWFM layer 130P) of the gate structure (e.g., gate structure 112). In some embodiments, the back contact structure can also surround the back surface and/or the sidewalls of the isolation structure (e.g., isolation structure 111) between the first and second nanostructured channel regions (e.g., nanostructured channel regions 108N and 108P). In some embodiments, the back contact structure can be formed by replacing the substrate (e.g., substrate 104) and fin portions (e.g., base structures 106N and 106P) under the first and second nanostructured channel regions and the isolation structure with the back contact structure. As a result, larger contact area can be formed between the back contact structure and the gate structures, which can significantly reduce the gate contact resistance and improve device performance. In addition, by replacing the substrate and fin portions with the back contact structure, the formation of isolation structures under S/D regions (e.g., S/D regions 110N and 110P) of the NFET and PFET (e.g., NFETs 102N and 202N, PFETs 102P and 202P) can be eliminated. Because, by removing the substrate and fin portions under the gate structure, the current leakage path between the source/drain regions are removed, thus eliminating the need for the isolation structures. Thus, the back contact structure can perform a dual function of (i) providing electrical signals from a power rail to both the NFET and PFET, and (ii) preventing current leakage between source/drain regions.

In some embodiments, a semiconductor device includes a substrate, first and second nanostructured channel regions, and a gate structure. The gate structure includes first and second metal layers surrounding the first and second nanostructured channel regions and a gate metal layer disposed on the first and second metal layers. The first and second metal layers are different from each other. The semiconductor device further includes an isolation structure disposed between and in contact with the first and second nanostructured channel regions and a first contact structure disposed on surfaces of the isolation structure and the first and second metal layers that faces the substrate.

In some embodiments, a semiconductor device includes a substrate, first and second nanostructured channel regions, first and second S/D regions disposed adjacent to the first and second nanostructured channel regions, respectively, and an isolation structure. The isolation structure includes a first isolation portion disposed between and in contact with the first and second nanostructured channel regions and a second isolation portion disposed between and in contact with the first and second source/drain regions. The semiconductor device further includes first and second metal layers disposed surrounding the first and second nanostructured channel regions, respectively, a third metal layer disposed on the first and second metal layers, and a contact structure disposed on back surfaces of the isolation structure and the first and second metal layers.

In some embodiments, a method includes forming a first superlattice structure with a first nanostructured layer and a first sacrificial nanostructured layer on a first base structure on a substrate, forming a second superlattice structure with a second nanostructured layer and a second sacrificial nanostructured layer on a second base structure on the substrate, forming an isolation structure between the first and second superlattice structures, forming a polysilicon structure on the isolation structure and the first and second superlattice structures, removing the polysilicon structure and the first and second sacrificial nanostructured layers to form a gate opening, depositing a first metal layer surrounding the first nanostructured layer in the gate opening, depositing a second metal layer surrounding the second nanostructured layer, depositing a third metal layer on the first and second metal layers, and forming a contact structure on back surfaces of the first and second metal layers.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
first and second nanostructured channel regions;
a gate structure, comprising:
a gate dielectric layer disposed on the first and second nanostructured channel regions,
first and second metal layers surrounding the first and second nanostructured channel regions, respectively, wherein the first and second metal layers are different from each other, and
a gate metal layer disposed on the first and second metal layers;
a gate spacer having a first sidewall interfacing the gate dielectric layer and a second sidewall facing away from the gate structure, wherein a dielectric constant of the gate dielectric layer is greater than a dielectric constant of the gate spacer and wherein a thickness of the gate spacer is greater than a thickness of the gate dielectric layer;
an isolation structure disposed between and in contact with the first and second nanostructured channel regions; and
a first contact structure disposed on surfaces of the isolation structure and the first and second metal layers that face the substrate.

2. The semiconductor device of claim 1, further comprising a second contact structure disposed on a top surface of the gate metal layer.

3. The semiconductor device of claim 1, wherein the first contact structure comprises a U-shaped cross-sectional profile.

4. The semiconductor device of claim 1, wherein the first contact structure comprises:
a conductive layer disposed on the surfaces of the isolation structure and the first and second metal layers that face the substrate;
an outer dielectric liner surrounding the conductive layer; and
an inner dielectric liner disposed on sidewalls of the isolation structure.

5. The semiconductor device of claim 1, wherein a back surface of the first contact structure is substantially coplanar with a back surface of the substrate.

6. The semiconductor device of claim 1, wherein the isolation structure extends vertically below a top surface of the first contact structure.

7. The semiconductor device of claim 1, wherein the isolation structure extends vertically above top surfaces of the first and second nanostructured channel regions.

8. The semiconductor device of claim 1, wherein the gate metal layer is different from the first and second metal layers.

9. The semiconductor device of claim 1, wherein the gate dielectric layer comprises a high-k dielectric layer and is disposed on a top surface and sidewalls of the isolation structure.

10. The semiconductor device of claim 1, wherein an interface between the first and second metal layers is disposed on the isolation structure.

11. A semiconductor device, comprising:
a substrate;
first and second nanostructured channel regions;
first and second source/drain regions disposed adjacent to the first and second nanostructured channel regions, respectively, wherein heights of the first and second source/drain regions and widths of the first and second source/drain regions are different from each other and wherein the first and second source/drain regions extend into the substrate;
an isolation structure, comprising:
a first isolation portion disposed between and in contact with the first and second nanostructured channel regions, and
a second isolation portion disposed between and in contact with the first and second source/drain regions;
first and second metal layers disposed surrounding the first and second nanostructured channel regions, respectively;
a third metal layer disposed on the first and second metal layers; and
a contact structure disposed on back surfaces of the isolation structure and the first and second metal layers.

12. The semiconductor device of claim 11, wherein the contact structure comprises a protruding portion, and wherein a first sidewall of the protruding portion is in contact with a sidewall of the first metal layer and a second sidewall of the protruding portion is in contact with a sidewall of the second metal layer.

13. The semiconductor device of claim 11, wherein the contact structure comprises a protruding portion, and wherein a width of the protruding portion is greater than a width of the isolation structure.

14. The semiconductor device of claim 11, wherein the contact structure comprises a protruding portion that extends laterally under the first and second nanostructured channel regions.

15. The semiconductor device of claim 11, wherein a back surface of the contact structure is substantially coplanar with a back surface of the substrate.

16. The semiconductor device of claim 11, wherein the contact structure comprises:
a conductive layer disposed on the back surfaces of the isolation structure and the first and second metal layers; and
a dielectric liner surrounding the conductive layer.

17. A method, comprising:
forming a first superlattice structure with a first nanostructured layer and a first sacrificial nanostructured layer on a first base structure on a substrate;
forming a second superlattice structure with a second nanostructured layer and a second sacrificial nanostructured layer on a second base structure on the substrate;
forming an isolation structure between the first and second superlattice structures;
forming a polysilicon structure on the isolation structure and the first and second superlattice structures;
epitaxially growing a source/drain regions in the substrate and adjacent to the first nanostructured layer;
removing the polysilicon structure and the first and second sacrificial nanostructured layers to form a gate opening;
depositing a first metal layer surrounding the first nanostructured layer in the gate opening;
depositing a second metal layer surrounding the second nanostructured layer;
depositing a third metal layer on the first and second metal layers;
depositing a dielectric layer on the third metal layer;
forming a first contact structure extending through the dielectric layer and on the source/drain region, wherein an electrical conductivity of the first contact structure is greater than an electrical conductivity of the source/drain region; and
forming a second contact structure on back surfaces of the first and second metal layers.

18. The method of claim 17, wherein forming the second contact structure comprises etching portions of the first and second base structures under the first and second nanostructured layers.

19. The method of claim 17, wherein forming the second contact structure comprises forming a portion of the substrate under the isolation structure.

20. The method of claim 17, wherein forming the second contact structure comprises etching a portion of the isolation structure that extends below the first and second metal layers.
